(19) United States
(12) Patent Application Publication
(10) Pub. No.: US 2023/0417954 A1
(43) Pub. Date: Dec. 28, 2023

(54) IN-SITU ALUMINIUM CLEANING USING ATOMIC LAYER ETCHING FOLLOWED BY ATOMIC LAYER DEPOSITION CAPPING FOR ENHANCED ALUMINIUM MIRRORS FOR VUV OPTICS

(71) Applicant: CORNING INCORPORATED, Corning, NY (US)

(72) Inventors: Donald Erwin Allen, Painted Post, NY (US); Narendra Shamkant Borgharkar, Fairport, NY (US); Ming-Huang Huang, Ithaca, NY (US); Hoon Kim, Horseheads, NY (US); Jue Wang, Pittsford, NY (US)

(21) Appl. No.: 18/210,461

(22) Filed: Jun. 15, 2023

Related U.S. Application Data
(60) Provisional application No. 63/354,257, filed on Jun. 22, 2022.

(51) Int. Cl. G02B 1/14; G02B 5/08; C23C 14/14; C23C 14/58; C23C 16/30; C23C 16/455; C23C 28/00

(52) U.S. Cl. CPC G02B 1/14; G02B 5/0891; C23C 14/14; C23C 14/5846; C23C 14/5873; C23C 16/30; C23C 16/45555; C23C 16/45527; C23C 16/45553; C23C 28/32; C23C 28/34

(57) ABSTRACT

A method of making an enhanced aluminium mirror for vacuum ultraviolet (VUV) optics includes depositing a reflective coating comprising aluminium metal to at least one surface of a substrate through physical vapor deposition (PVD) to produce a mirror comprising the substrate and the reflective coating. The method further includes removing aluminium oxides from an outer surface of the reflective coating by conducting atomic layer etching (ALE) in an Atomic Layer Deposition (ALD) system to produce an etched surface of the reflective coating and depositing an ALD protective layer onto the etched surface of the reflective coating by conducting atomic layer deposition in the ALD system to produce the enhanced aluminium mirror. The enhanced aluminium mirror includes the substrate, the reflective coating deposited on the substrate, and the ALD protective layer covering the etched surface of the reflective coating.

This application claims the benefit of priority under 35 U.S.C § 120 of U.S. Provisional Application Ser. No. 63/354,257 filed on Jun. 22, 2022, the content of which is relied upon and incorporated herein by reference in its entirety.

### BACKGROUND

### Field

The present disclosure generally relates to optical components, more specifically, to methods for producing enhanced aluminium mirrors for vacuum ultraviolet (VUV).

### Technical Background

Optical technology utilizing ultraviolet light is in wide use in semiconductor manufacturing. Advanced lithography technology enables formation of smaller feature sizes for microelectronics. This technology advancement also demands sensitive optical inspection that allows defect detection down to the nano-scale range. Currently defect inspection is dominated by deep-ultraviolet (DUV) optics, which operate at wavelengths of about 193.4 nm. Next generation optical inspection optics are expected to be dominated by vacuum ultraviolet (VUV) optics (e.g., wavelengths of from 120 nm-190 nm) and extreme ultraviolet (EUV) optics (e.g., wavelengths down to about 13.5 nm). Although the EUV wavelengths are up to 10 times shorter than the VUV wavelengths, many microelectronics defects are optically more sensitive to both the VUV and the EUV wavelengths, compared to DUV optics. As a result, development of VUV and EUV inspection optics is an important focus for the semiconductor industry.

The performance of VUV optical inspection systems depends on VUV mirrors. Aluminium is recognized as the primary material for producing VUV reflective optics, such as VUV mirrors. Aluminium is typically applied to a substrate using physical vapor deposition (PVD) to deposit the aluminium onto the surface of the substrate to create a reflective surface. PVD-Al mirrors can provide a reflectance of greater than 90% over the VUV wavelength range. However, degradation of the PVD-AL coating over time due to oxidation can greatly reduce the reflective performance of the PVD-AL coatings.

### SUMMARY

Accordingly, an ongoing need exists for enhanced aluminium mirrors and methods for producing enhanced aluminium mirrors for VUV optics, where the methods reduce defects and protect the aluminium reflective coating from degradation caused by oxidation of the aluminium.

According to a first aspect of the present disclosure, a method of making an enhanced aluminium mirror for vacuum ultraviolet (VUV) optics may include depositing a reflective coating comprising aluminium metal to at least one surface of a substrate through physical vapor deposition (PVD) in a PVD system to produce a mirror comprising the substrate and the reflective coating. The method may further include removing aluminium oxides from an outer surface of the reflective coating by conducting Atomic Layer Etching (ALE) in an Atomic Layer Deposition (ALD) system to produce an etched surface of the reflective coating. The method may further include depositing an ALD protective layer onto the etched surface of the reflective coating by conducting atomic layer deposition in the ALD system to produce the enhanced aluminium mirror comprising the substrate, the reflective coating deposited on the substrate, and the ALD protective layer covering the etched surface of the reflective coating.

A second aspect of the present disclosure may include the first aspect, further comprising transferring the substrate comprising the reflective coating from the PVD system to the ALD system, where transferring the substrate having the reflective coating to the ALD system can expose the reflective coating to oxygen resulting in oxidation of aluminium at an outer surface of the reflective coating to form aluminium oxides.

A third aspect of the present disclosure may include either one of the first or second aspects, wherein the atomic layer etching in the ALD system may comprise exposing the substrate and the reflective coating to alternating pulses of a fluorine source and an organometallic compound. Exposing the substrate and reflective coating to a pulse comprising the fluorine source may convert the aluminium oxides to aluminium fluoride to form a thin layer of aluminium fluoride on the outer surface of the reflective coating. Exposing the thin layer of aluminium fluoride to a pulse comprising the organometallic compound may cause the aluminium fluoride to react to form a volatile organometallic compound that may be released from the outer surface of the reflective coating.

A fourth aspect of the present disclosure may include the third aspect, comprising exposing the reflective coating to alternating pulses of the fluorine source and the organometallic compound at a temperature of from 150° C. to 325° C., or from 200° C. to 250° C.

A fifth aspect of the present disclosure may include either one of the third or fourth aspects, comprising exposing the etched surface of the reflective coating to the alternating pulses of the fluorine source and the organometallic compound at from 50 Watts (W) to 600 W.

A sixth aspect of the present disclosure may include any one of the third through fifth aspects, comprising exposing the etched surface of the reflective coating to the fluorine source for an exposure time of from 1 second to 60 seconds.

A seventh aspect of the present disclosure may include the sixth aspect, further comprising, after exposing the etched surface of the reflective coating to the fluorine source for the exposure time, purging an ALD chamber of the ALD system with an inert gas for a purge time sufficient to remove at least 99% of the residual fluorine source and oxygen compounds from the ALD chamber.

An eighth aspect of the present disclosure may include any one of the third through seventh aspects, wherein the fluorine source may comprise sulfur hexafluoride (SF₆), nitrogen trifluoride (NF₃), trifluoroiodomethane (CF₃I), hydrogen fluoride (HF), SF₆ plasma, SF₆ and argon (Ar) plasma, NF₃ plasma, NF₃ and Ar plasma, or combinations of these.

A ninth aspect of the present disclosure may include any one of the third through eighth aspects, wherein the fluorine source may comprise SF₆, SF₆ plasma, or a plasma comprising SF₆ and argon (Ar).

A tenth aspect of the present disclosure may include any one of the third through ninth aspects, wherein the organometallic compound may comprise trimethylaluminium (TMA), triethylaluminium (TLA), dimethylaluminium chloride (DMAC), silicon tetrachloride (SiCl₄), aluminium hexafluoroacetylacetonate (Al(hfac)₃), tri-i-butylaluminium (Al(iBu)₃), tin(II) acetylacetonate (Sn(acac)₂), tris(2,2,6,6-tetramethyl-3,5-heptanedionato)aluminium (i.e., Al(TMHD)₃, or combinations of these.

An eleventh aspect of the present disclosure may include any one of the third through tenth aspects, comprising exposing the thin layer of aluminium fluoride to the organometallic compound for a total exposure time of from 10 milliseconds (ms) to 60,000 ms, or from 10 ms to 30,000 seconds, where the total exposure time is equal to a pulse length of the pulse of the organometallic compound and a shut-in period.

A twelfth aspect of the present disclosure may include any one of the third through eleventh aspects, comprising exposing the thin layer of aluminium fluoride to the organometallic compound at a pressure of from 10 millitorr (1.33 Pa) to 100 torr (13,332 Pa).

A thirteenth aspect of the present disclosure may include any one of the third through twelfth aspects, wherein exposing the thin layer of aluminium fluoride to the pulse comprising the organometallic compound may comprise injecting the organometallic compound into the ALD chamber for a pulse length and closing a throttle valve of the ALD system. Closing the throttle valve may prevent flow of materials into or out of the ALD chamber and may maintain the thin layer of aluminium fluoride in contact with the organometallic compound for a shut in period of from 1 second to 60 seconds, or from 10 seconds to 30 seconds.

A fourteenth aspect of the present disclosure may include the thirteenth aspect, further comprising reopening the throttle valve and purging the ALD chamber with an inert gas to remove at least 99% of the residual organometallic compounds, the volatile organometallic compounds, or both from the ALD chamber.

A fifteenth aspect of the present disclosure may include any one of the third through fourteenth aspects, wherein the atomic layer etching may have an etch rate of 1.1 Angstroms of thickness per cycle, wherein one complete cycle comprises one pulse of the fluorine source and one pulse of the organometallic compound.

A sixteenth aspect of the present disclosure may include any one of the first through fifteenth aspects, wherein the ALD protective layer may comprise a metal fluoride protective coating.

A seventeenth aspect of the present disclosure may include the sixteenth aspect, wherein the metal fluoride protective coating may comprise one or more of aluminium trifluoride (AlF₃), magnesium fluoride (MgF₂), calcium fluoride (CaF₂), lithium fluoride (LiF), lanthanum fluoride (LaF₃), gadolinium fluoride (GdF₃), or combinations of these.

An eighteenth aspect of the present disclosure may include any one of the first through seventeenth aspects, wherein applying the protective ALD coating on the outer surface of the etched aluminium layer may comprise exposing the etched aluminium layer to alternating pulses of a metal precursor and a fluorine source.

A nineteenth aspect of the present disclosure may include the eighteenth aspect, wherein the fluorine source may comprise sulfur hexafluoride (SF₆), nitrogen trifluoride (NF₃), trifluoroiodomethane (CF₃I), hydrogen fluoride (HF), SF₆ plasma, SF₆ and argon (Ar) plasma, NF₃ plasma, NF₃ and Ar plasma, or combinations of these.

A twentieth aspect of the present disclosure may include either one of the eighteenth or nineteenth aspects, wherein the fluorine source may comprise SF₆, an SF₆ plasma, or a plasma comprising SF₆ and argon (Ar).

A twenty-first aspect of the present disclosure may include any one of the eighteenth through twentieth aspects, wherein the metal precursor may comprise an aluminium precursor selected from one or more of trimethylaluminium (TMA), triethylaluminium (TEA), dimethylaluminium isopropoxide (DMAI), [MeC(NiPr)₂]AlEt₂, dimethylaluminiumhydride, dimethylethylamine, ethylpiperidine, dimethylaluminium hydride, or combinations of these.

A twenty-second aspect of the present disclosure may include any one of the eighteenth through twenty-first aspects, wherein the metal precursor may comprise a magnesium precursor selected from the group consisting of bis(ethylcyclopentadienyl)magnesium, bis(cyclopentadienyl)magnesium, bis(2,2,6,6-tetramethyl-3,5-heptanedionato)magnesium, bis(N,N′-di-sec-butylacetamidinato) magnesium, bis(pentamethylcyclopentadienyl)magnesium, and combinations of these.

A twenty-third aspect of the present disclosure may include any one of the eighteenth through twenty-second aspects, wherein the ALD may have growth rate of the protective ALD coating of 0.5 Angstroms of thickness per cycle, wherein one complete cycle of the ALD process comprises one pulse of the fluorine source and one pulse of the organometallic compound.

A twenty-fourth aspect of the present disclosure may include any one of the eighteenth through twenty-third aspects, further comprising exposing the surface to a pulse containing an oxygen source after exposing the surface to the pulse comprising the metal precursor and before exposing the surface to the pulse comprising the fluorine source. The metal precursor may form a ligated metal at the outer surface of the article. The oxygen source may cause oxidation of the ligated metal to form a metal oxide. The fluorine source may reduce the metal oxide to form the metal fluoride of the protective ALD coating.

A twenty-fifth aspect of the present disclosure may include the twenty-fourth aspect, wherein the oxygen source may comprise water, water plasma, oxygen, oxygen plasma, ozone, ozone plasma, hydrogen peroxide, hydrogen peroxide plasma, oxygen-containing liquid, oxygen-containing gas, or combinations of these.

A twenty-sixth aspect of the present disclosure may include any one of the first through twenty-fifth aspects, comprising depositing a first ALD protective layer on the etched surface of the reflective coating and depositing a second ALD protective layer on an outer surface of the first ALD protective layer.

A twenty-seventh aspect of the present disclosure may include any one of the first through twenty-sixth aspects, where the ALD protective layer may comprise a high reflective index metal fluoride, wherein the high reflective index metal fluoride may increase the reflectance of the enhanced aluminium mirror relative to a mirror comprising only the reflective coating.

A twenty-eighth aspect of the present disclosure may be directed to an enhanced aluminium mirror for ultraviolet optical systems. The enhanced aluminium mirror may comprise a substrate having a surface, and a reflective coating deposited onto the surface of the substrate, wherein the reflective coating comprises aluminium metal deposited by physical vapor deposition. The enhanced aluminium mirror may further include an ALD protective layer deposited onto an etched surface of the reflective coating. The ALD protective layer may be applied through atomic layer deposition, the reflective coating may reflects light having wavelengths in at least the vacuum ultraviolet wavelength range, and the ALD protective layer may reduce or prevent oxidation of the aluminium of the reflective coating.

A twenty-ninth aspect of the present disclosure may include the twenty-eighth aspect, wherein the reflective coating and the ALD protective layer may contain less than 5 atomic percent oxygen atoms.

A thirtieth aspect of the present disclosure may include either one of the twenty-eighth or twenty-ninth aspects, wherein the enhanced aluminium mirror does not have a layer of aluminium oxide disposed between the reflective coating and the ALD protective layer.

A thirty-first aspect of the present disclosure may include any one of the twenty-eighth through thirtieth aspects, wherein the ALD protective layer may comprise a high reflective index metal fluoride, wherein the high reflective index metal fluoride may increase the reflectance of the enhanced aluminium mirror relative to a mirror comprising only the reflective coating.

A thirty-second aspect of the present disclosure may include the thirty-first aspect, wherein the high reflective index metal fluoride may comprise lanthanum fluoride, gadolinium fluoride, or both.

A thirty-third aspect of the present disclosure may include any one of the twenty-eighth through thirty-second aspects, wherein the ALD protective layer may comprise a first ALD protective layer comprising a first ALD metal fluoride and a second ALD protective layer comprising a second ALD metal fluoride that is different from the first ALD metal fluoride.

Additional features and advantages of the enhanced aluminium mirrors and the methods of producing the enhanced aluminium mirrors described herein will be set forth in the detailed description that follows, and in part will be readily apparent to those skilled in the art from that description or recognized by practicing the embodiments described herein, including the detailed description that follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a perspective view of an enhanced aluminium mirror for VUV optics, according to one or more embodiments shown and described herein;

FIG. 2 schematically depicts a cross-sectional view of a portion of an enhanced aluminium mirror, according to one or more embodiments shown and described herein;

FIG. 3 schematically depicts a cross-sectional view of a portion of an aluminium mirror comprising only a PVD aluminium coating, according to the prior art;

FIG. 4 graphically depicts percent reflectance (y-axis) as a function of wavelength of light (x-axis) for a pure aluminium reflective coating and for oxidized aluminium reflective coatings having various degrees of oxidation of the outer surface of the aluminium to aluminium oxide, according to one or more embodiments shown and described herein;

FIG. 5 schematically depicts a flow chart for a PVD-only method of forming an aluminium mirror comprising a PVD protective metal fluoride coating on the aluminium mirror of FIG. 3, according to the prior art;

FIG. 6 schematically depicts a flow chart for a hybrid method comprising PVD for depositing an aluminium reflective coating and a low-density PVD-AlF₃ layer and further comprising Atomic Layer Deposition (ALD) for applying a protective metal fluoride layer on an outer surface of the low-density PVD-AlF₃ layer, according to one or more embodiments shown and described herein;

FIG. 7 schematically depicts a cross-sectional view of a portion of an aluminium mirror produced according to the method shown in the flow chart of FIG. 6, according to one or more embodiments shown and described herein;

FIG. 8A graphically depicts reflectance (y-axis) as a function of wavelength of light (x-axis) for the aluminium mirrors of FIGS. 3 and 7 and the enhanced aluminium mirror of FIG. 2; according to one or more embodiments shown and described herein;

FIG. 8B graphically depicts reflectance (y-axis) as a function of wavelength of light (x-axis) for the aluminium mirror of FIG. 3 and the enhanced aluminium mirror of FIG. 2; according to one or more embodiments shown and described herein;

FIG. 8C graphically depicts reflectance (y-axis) as a function of wavelength of light (x-axis) for the aluminium mirror of FIG. 3 and the enhanced aluminium mirror of FIG. 2 with an ultraviolet treatment; according to one or more embodiments shown and described herein;

FIG. 9 schematically depicts a flow chart of a method for producing the enhanced aluminium mirror of FIG. 2, according to one or more embodiments shown and described herein;

FIG. 10 schematically depicts an ALD system for conducting an ALE process and an ALD processes of the method of FIG. 9, according to one or more embodiments shown and described herein;

FIG. 11 schematically depicts an enhanced aluminium mirror having a plurality of ALD protective layers applied to a surface of a reflective layer, according to one or more embodiments shown and described herein;

FIG. 12 graphically depicts a SIMS depth profile for an enhanced aluminium mirror having a 4 nm ALD-AlF₃ protective layer applied to an etched surface of the reflective layer, according to one or more embodiments shown and described herein;

FIG. 13 graphically depicts a SIMS depth profile for an enhanced aluminium mirror having a 12 nm ALD-AlF₃ protective layer applied to an etched surface of the reflective layer and a 9 nm ALD-MgF₂ protective layer applied on top of the ALD-AlF₃ protective layer, according to one or more embodiments shown and described herein;

FIG. 14 graphically depicts a SIMS depth profile for an aluminium mirror having a protective layer comprising 15 nm low-density PVD-AlF₃ layer and a 10 nm dense PVD-AlF₃ layer, according to the prior art;

FIG. 15 graphically depicts a SIMS depth profile for an aluminium mirror made according to the hybrid method in FIG. 6 and having 15 nm low-density PVD-AlF₃ layer and a 10 nm ALD-AlF₃ layer, according to one or more embodiments shown and described herein;

FIG. 16 graphically depicts reflection (y-axis) as a function of wavelength (x-axis) for a PVD-only aluminium mirror after exposure to UV ozone for designated periods of time, according to one or more embodiments shown and described herein;

FIG. 17 graphically depicts reflection (y-axis) as a function of wavelength (x-axis) for an enhanced aluminium mirror having an ALD protective layer with a thickness of 4 nm after exposure to UV ozone for designated periods of time, according to one or more embodiments shown and described herein;

FIG. 18 graphically depicts % reflectance (y-axis) as a function of wavelength (x-axis) for an enhanced aluminium mirror having a first ALD protective layer comprising ALD-AlF₃ and a second ALD protective layer comprising a high reflective index metal fluoride (ALD-LaF₃), according to one or more embodiments shown and described herein;

FIG. 19A graphically depicts reflectance (y-axis) as a function of wavelength of light (x-axis) for the enhanced aluminium mirror of FIG. 2 before and after a humidity test; according to one or more embodiments shown and described herein; and

FIG. 19B graphically depicts reflectance (y-axis) as a function of wavelength of light (x-axis) for the aluminium mirror of FIG. 3 before and after a humidity test.

### DETAILED DESCRIPTION

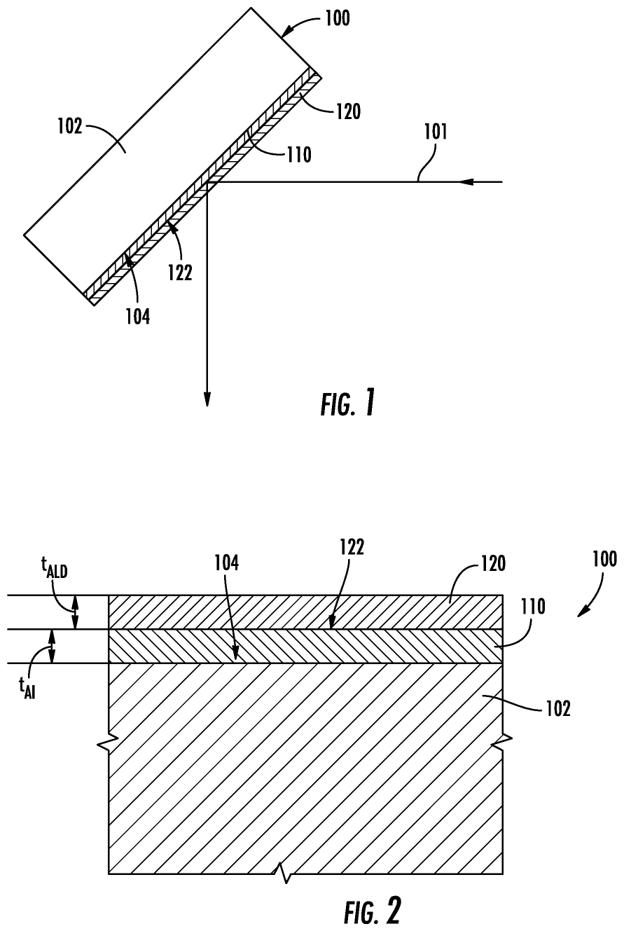

Reference will now be made in detail to various embodiments of enhanced aluminium mirrors and methods of making the enhanced aluminium mirrors for VUV optics, according to the present disclosure. Examples of the enhanced aluminium mirrors and methods disclosed herein are schematically depicted in the accompanying drawings. Whenever possible, the same reference numerals will be used throughout the drawings to refer to the same or like parts. Referring now to FIGS. 1 and 2, an enhanced aluminium mirror 100 for VUV optics according to the present disclosure comprises a substrate 102, a reflective coating 110 deposited onto a mirror surface 104 of the substrate 102, and at least one ALD protective layer 120 deposited onto an etched surface 122 of the reflective coating 110. The reflective layer 110 is aluminium metal and can be deposited onto the substrate 102 through physical vapor deposition (PVD). The ALD protective layer 120 can be a metal fluoride layer applied by atomic layer deposition (ALD).

A method of making the enhanced aluminium mirror 100 can include depositing the reflective coating 110 comprising aluminium metal to at least one mirror surface 104 of the substrate 102 through a PVD process in a PVD system to produce a mirror comprising the substrate 102 and the reflective coating 110. The method can further include removing aluminium oxides from the outer surface of the reflective coating 110 by conducting atomic layer etching (ALE) in an Atomic Layer Deposition (ALD) system to produce the etched surface 122 of the reflective coating 110 and depositing the ALD protective layer 120 onto the etched surface 122 of the reflective coating 110 by conducting an ALD process in the ALD system to produce the enhanced aluminium mirror 100 comprising the substrate 102, the reflective coating 110 deposited on the substrate 102, and the ALD protective layer 120 covering the etched surface 122 of the reflective coating 110.

Various embodiments of the enhanced aluminium mirrors 100 and the methods of making the enhanced aluminium mirrors 100 will be described herein with specific reference to the appended drawings.

As used herein, the term “substantially free” of a constituent may refer to a composition, fiber, or atmosphere that includes less than 0.01 percent by weight or by mole of the constituent. For example, an ALD coating that is substantially free of carbon may include less than 0.01 percent by weight or by mole carbon.

The terms “microns” and “μm” are used interchangeably herein. The terms “nanometers” and “nm” are used interchangeably herein.

As used herein, the term “plasma” refers to a gas of ions that includes positive ions and electrons, and is generated from a starting material through application of heat and an electric current.

As used herein, the term “ppm” means parts per million on a molar basis and represents an atomic concentration. For example, a layer of MgF₂ with 1 ppm carbon includes 1 mole of carbon per million moles of MgF₂.

As used herein, the term “conformal coating” refers to a coating that conforms to the contours of the surfaces of an article and has generally uniform thickness over all of the surfaces contacted by the coating.

As used herein, the term “passivation” refers to treating or coating a surface of an article to make the surface more passive, meaning to make the surface less reactive with the environment.

As used herein, the term “mirror surface” refers to an outer surface of a substrate to which the reflective coating is applied and is not intended to imply that the outer surface is mirrored prior to depositing the reflective coating.

As previously discussed, the performance of VUV and EUV optics for inspection of microelectronics and semiconductors can depend on the quality and reflectance of mirrors, which are incorporated into the optical inspection systems to direct the VUV and EUV wavelength light along the inspection path. Aluminium is commonly used for coating substrates to produce reflective optics (i.e., mirrors) for VUV and EUV optics systems. Aluminium is typically applied to the surface of a substrate using physical vapor deposition (PVD) to deposit the aluminium onto the surface of the substrate to create a reflective surface. PVD-Al mirrors can provide a reflectance of greater than 90% over the VUV wavelength range.

Referring to FIG. 3, one embodiment of a typical mirror 200 for ultraviolet optics is schematically depicted. The mirror 200 includes a substrate 102 comprising at least one surface, which is referred to herein as the mirror surface 104, and a reflective coating 110 applied to the mirror surface 104 of the substrate 102. The reflective coating 110 can be an aluminium coating comprising, consisting of, or consisting essentially of aluminium metal. The reflective coating 110 can be aluminium metal applied through Physical Vapor Deposition (PVD), according to known methods. The reflective coating 110 can have an outer surface 112 that can reflect greater than 90% of VUV wavelength light incident on the outer surface 112, when the outer surface 112 is pure aluminium. In operation of the mirror 200, a beam comprising VUV wavelength light can be directed at the mirror 200. The beam of VUV wavelength light incident on the outer surface 112 of the reflective coating 110 is reflected from the outer surface 112 of the reflective coating 110 along a different path from the original beam.

Reflective coatings 110 comprising aluminium applied to the substrate through a PVD process can degrade over time due to oxidation of the aluminium. Oxidation of the aluminium can greatly reduce the reflectivity of the aluminium reflective coating 110. Referring to FIG. 3, the mirror 200 comprising only the reflective coating 110 is schematically depicted. For the mirror 200 in FIG. 3, the aluminium 114 of the reflective layer 110 can oxidize to form aluminium oxide (Al₂O₃) at the outer surface 112 of the reflective layer 110. The aluminium oxide can form an aluminium oxide layer 116 on top of the aluminium 114. The aluminium oxide layer 116 changes the optical properties of the mirror 100, which can reduce the reflectance of the mirror 200. The reflectance of the mirror 200 decreases with increasing thickness t_{Al2O3} of the aluminium oxide layer 116.

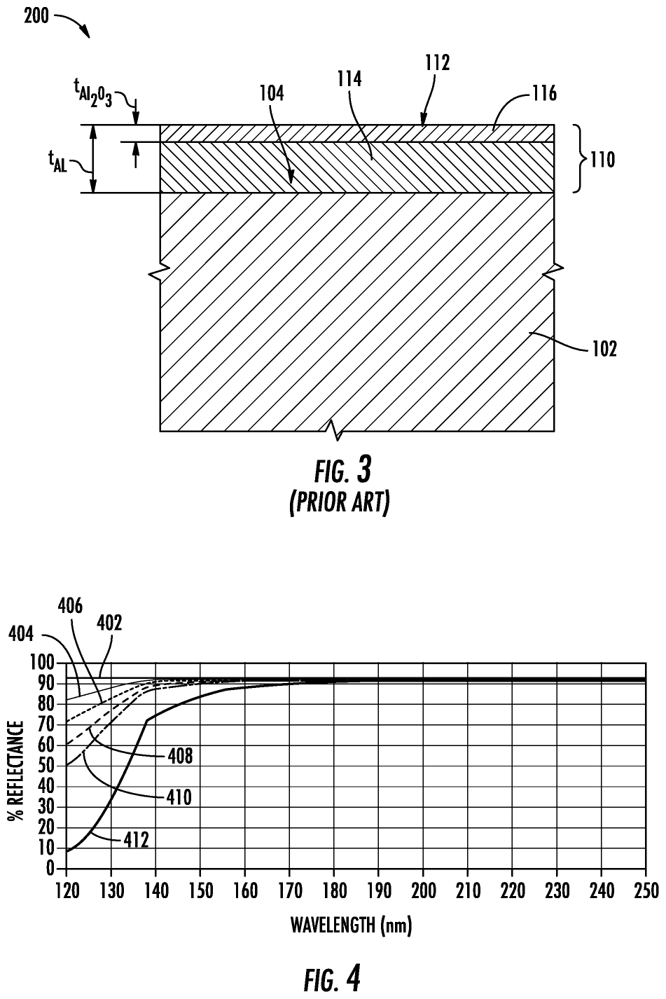

Referring now to FIG. 4, the VUV reflectance of a pure aluminium mirror as a function of wavelength is compared to the VUV reflectance of mirrors comprising one or more monolayers of Al₂O₃ formed on the top of the aluminium reflective layer through surface oxidation. A monolayer of Al₂O₃ refers to a single molecule layer of Al₂O₃ having a thickness that is approximately the length or diameter of one molecule of Al₂O₃. The following Table 1 provides correspondence between the reference numbers in FIG. 4 and the number of Al₂O₃ monolayers formed on the outer surface of the aluminium reflective coating. As previously discussed, VUV includes wavelengths of from 120 nm to 190 nm. At the low end of the VUV range of 120 nm wavelength, for example, the reflectance of a pure Al mirror is as high as 92%. The reflectance decreases as the Al surface oxidation proceeds and the thickness t_{Al2O3} of the Al₂O₃ layer increases. The reflectance is reduced to 50% when the oxidation layer thickness t_{Al2O3} reaches 1.2 nm, which corresponds to four single molecule layers of Al₂O₃ (ref no. 410 in FIG. 4). If an aluminium mirror is not protected or passivated, oxidation of the aluminium can result in an Al₂O₃ layer of up to 3 nm. The native oxidation corresponding to 10 Al₂O₃ monolayers (ref. no. 412) has a thickness t_{Al2O3} of around 3 nm, which reduces the reflectance of the aluminium mirror down to less than 10% at 120 nm wavelength, as shown in FIG. 4.

TABLE 1

| | # Al₂O₃ | Reference Number |
|---|---|---|
| Mirror | Monolayers | in FIG. 4 |
| Pure aluminium - no Al₂O₃ | 0 | 402 |
| Single monolayer of Al₂O₃ | 1 | 404 |
| Two monolayers of Al₂O₃ | 2 | 406 |
| Three monolayers of Al₂O₃ | 3 | 408 |
| Four monolayers of Al₂O₃ | 4 | 410 |
| Ten monolayers of Al₂O₃ | 10 | 412 |

To reduce or prevent oxidation of the aluminium of the reflective coating 110, the aluminium of the reflective coating 110 can be coated with a protective layer. In some cases, PVD can be used to apply the protective layer onto the outer surface 112 of the reflective coating 110. The current best practice for aluminium mirrors is to apply PVD based metal fluorides, such as but not limited to PVD magnesium fluoride (PVD-MgF₂) or PVD aluminium fluoride (PVD-AlF₃), to the outer surface 112 of the reflective coating 110 to form the protective layer. Referring now to FIG. 5, these conventional aluminium mirrors can be prepared by a method 500 that includes loading the substrate into the PVD chamber in step 502, depositing PVD aluminium (PVD-Al) in step 504 to create the reflective layer, depositing an initial low density PVD aluminium fluoride (PVD-AlF₃) layer in step 506, and then heating the mirror and depositing an additional dense PVD-AlF₃ layer on top of the initial low density PVD-AlF₃ in step 508. In step 504, the PVD-Al layer is deposited under vacuum at room temperature at a high deposition rate in the PVD chamber. In step 506, the initial low density PVD-AlF₃ layer can be deposited at room temperature just after deposition of the PVD-Al coating. The initial low density PVD-AlF₃ layer is typically about 15 nm in thickness. In step 508, the PVD chamber and mirror disposed therein are heated to about 200° C. for deposition of the dense PVD-AlF₃ layer. The thickness of the dense PVD-AlF₃ is typically around 10 nm. In step 510, the mirror can be removed from the PVD chamber. Although the initial low density PVD-AlF₃ layer provides some protection from oxidation of the PVD-Al coating, aluminium oxidation still occurs, albeit at a reduced rate, during heating of the mirror to 200° C. in the PVD chamber prior to depositing the dense PVD-AlF₃ layer in step 508 of FIG. 5. Additionally, PVD-AlF₃ coatings can exhibit pin holes and inconsistent thickness regions that can provide pathways for air and other oxidizing agents to oxidize the surface of the reflective layer 110. Thus, applying a dense PVD-Al coating still suffers from the problem of aluminium oxide formation at the outer surface of the aluminium reflective layer, which affects the reflectance of the aluminium mirror.

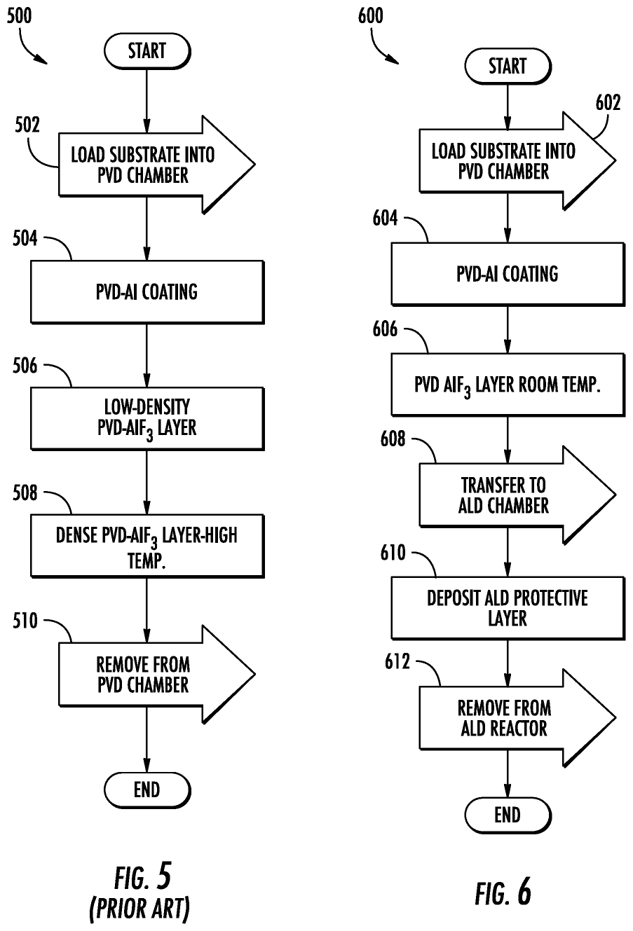

Atomic Layer Deposition (ALD) can provide a protective metal fluoride layer that has a lower oxygen penetration rate compared to PVD coatings and, thus, can improve the passivation behavior of the aluminium mirror. Referring now to FIG. 6, a hybrid method 600 for producing an aluminium mirror can include PVD coating of the PVD-Al reflective layer and the initial low-density PVD-AlF₃ layer followed by deposition of an ALD protective layer. According to the hybrid method 600 in FIG. 6, the substrate is first loaded into the PVD chamber of the PVD process in step 602. In step 604, the PVD-Al layer is deposited under vacuum at room temperature at a high deposition rate in the PVD chamber to produce the reflective layer of PVD-Al. In step 606, the initial low-density PVD-AlF₃ layer can be deposited at room temperature just after deposition of the PVD-Al coating to provide an initial protective coating. Following deposition of the low density PVD-AlF₃, the mirror is transferred from the PVD chamber to an ALD chamber of an ALD system in step 608. In step 610, the ALD protective layer is applied to the outer surface of the low-density PVD-AlF₃ layer. Following deposition of the ALD protective layer, the mirror comprising the hybrid protective coating (e.g., low-density PVD-AlF₃+ALD protective layer) can be removed from the ALD chamber in step 612.

Although the ALD-AlF₃ layer applied in step 610 of FIG. 6 has a lower oxygen penetration rate compared to the dense PVD-AlF₃ film applied in the method 500 of FIG. 5, the oxygen accumulation at the outer surface of the aluminium reflective layer is similar to the PVD-only mirror produced by the method 500 in FIG. 5. In particular, in order to apply an ALD coating, the mirror with the PVD-Al coating and the initial low-density PVD-AlF₃ layer must be transferred from the PVD chamber of the PVD system to the ALD chamber of the ALD system. It is noted that ALD coating processes require different atmospheres and operating conditions that generally cannot be accomplished in a typical PVD system. Transferring the mirror comprising the substrate, PVD-Al reflective layer, and the initial low-density PVD-AlF₃ layer exposes the partially formed mirror to air or other atmospheres comprising oxygen or other oxidizing constituents. The oxygen can react with the aluminium to form aluminium oxides at the surface of the PVD-Al reflective layer, which can build-up to form an aluminium oxide layer at the surface of the aluminium reflective layer. In some cases, the surface of the mirror can be cleaned with a fluorine source in the ALD chamber prior to applying the ALD-AlF₃ coating. However, cleaning with a fluorine source in the ALD coating is not effective to remove all the aluminium oxides at the surface of the reflective layer comprising the PVD-Al.

Referring now to FIG. 7, a mirror 300 made by the hybrid method 600 of FIG. 6 is graphically depicted. As shown in FIG. 7, the mirror 300 comprises the substrate 102 and the reflective coating 110, which can include the aluminium 114 from the PVD-Al coating process. The mirror 300 further includes the low-density PVD-AlF₃ layer 130 disposed on top of the reflective coating 110, and the ALD-AlF₃ protective layer 120 deposited on top of the low-density PVD-AlF₃ layer 130. Through exposure to air when transferring the mirror 300 from the PVD chamber to the ALD chamber, the mirror 300 can also include an aluminium oxide layer 116. The aluminium oxide layer 116 may be disposed between the aluminium 114 of the reflective coating 110 and the low-density PVD-AlF₃ layer 130.

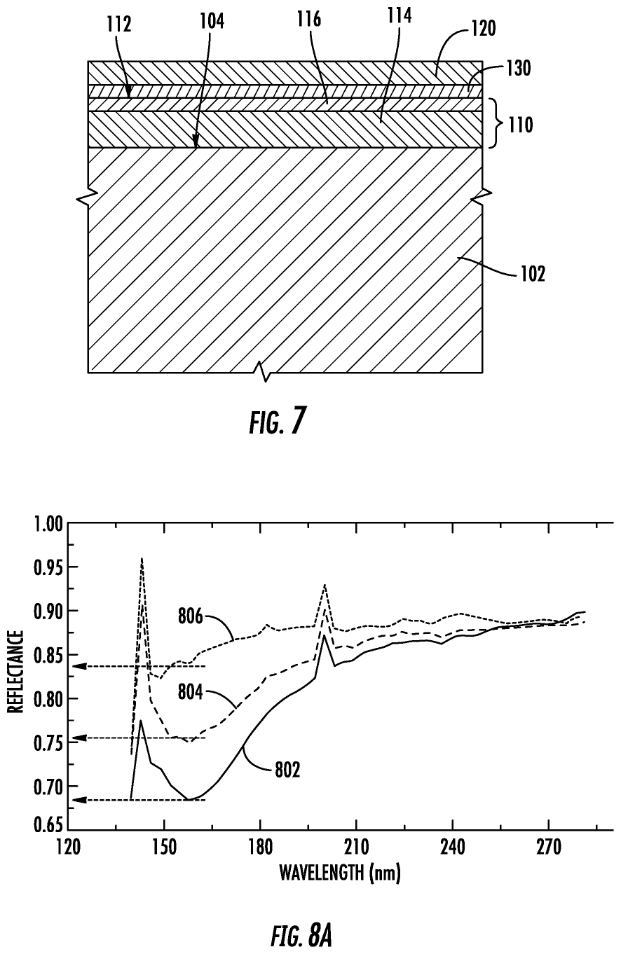

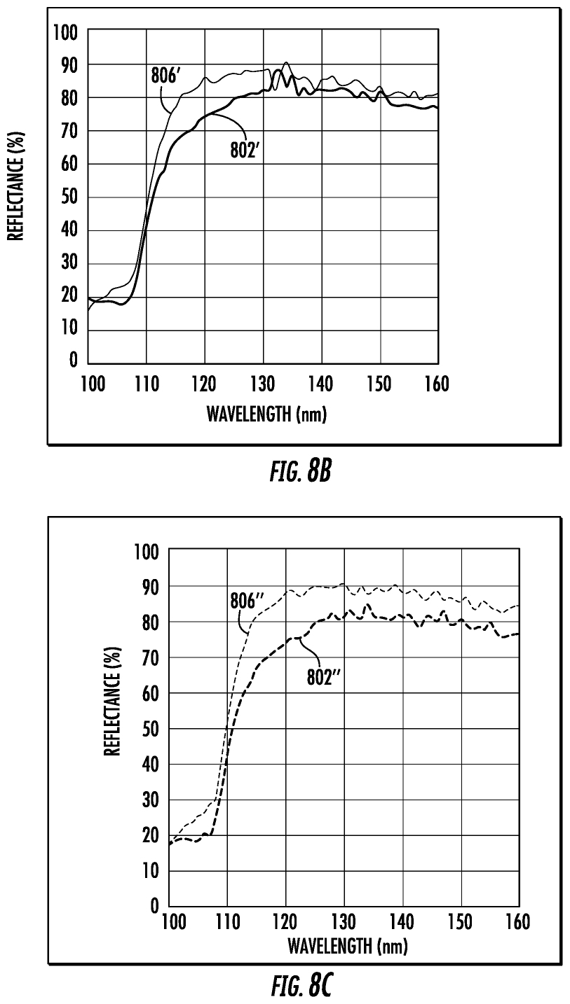

The formation of the aluminium oxides in the mirror 300 formed by the hybrid method can reduce the reflectance of the mirror 300 in the VUV wavelength region. Referring now to FIG. 8A, the reflectance (y-axis) as a function of wavelength (x-axis) is schematically depicted for an aluminium mirror made by the process of FIG. 5 (ref. no. 802) and an aluminium mirror made by the process of FIG. 6 (ref. no. 804 in FIG. 8A). The aluminium mirror for series 802 in FIG. 8A included a 100 nm PVD-Al reflective coating, a 15 nm low-density PVD-AlF₃ layer, and a 10 nm dense PVD-AlF₃ layer applied at 200° C. The aluminium mirror for series 804 was prepared by the method of FIG. 6 with the addition of a fluorine cleaning treatment prior to depositing the ALD protective layer to remove at least some of the carbon and oxygen impurities. The fluorine treatment comprised exposing the mirror to sulfur hexafluoride (SF₆) plasma at 150° C. for a period of 30 seconds and was conducted after transferring the aluminium mirror from the PVD chamber to the ALD chamber. The aluminium mirror of series 804 included a 100 nm PVD-Al reflective coating, a 15 nm low-density PVD-AlF₃ layer, and a 10 nm ALD-AlF₃ protective layer. The ALD-AlF₃ protective layer was applied according to the methods disclosed herein at a temperature of 150° C.

As shown in FIG. 8A, the PVD-only aluminium mirror 802 shows a significant reduction in reflectance down to 0.70 at wavelengths between 150 and 180, indicating the presence of aluminium oxides in the various coating layers. The aluminium mirror 804 comprising the PVD-Al layer, low-density PVD-AlF₃ layer, and the ALD-AlF₃ protective layer also exhibited a substantial decrease in reflectance of down to about 0.75 between 150 nm and 180 nm wavelengths. Though providing better reflectance performance compared to the PVD-only aluminium mirror 802, the aluminium mirror 804 prepared by the hybrid method of FIG. 6 still exhibits degradation of the reflectance performance over the VUV wavelength range due to oxidation of aluminium and accumulation of aluminium oxides in the reflective coatings and protective layers. Thus, ongoing needs exist for preparing enhanced aluminium mirrors for VUV wavelength applications, where the methods reduce the presence of aluminium oxides in the enhanced aluminium mirror.

The present disclosure is directed to enhanced aluminium mirrors and a process for producing the enhanced aluminium mirrors for VUV optics that further reduces the amount of aluminium oxides in the enhanced aluminium mirror and provides one or more ALD protective layers to reduce or prevent oxidation and degradation of the aluminium of the reflective layer during use of the enhanced aluminium mirrors. The methods of the present disclosures solve the problems in the previously discussed methods by incorporating an atomic layer etching (ALE) step after transferring the mirror with the PVD-Al reflective layer from the PVD system to the ALD system. In particular, the methods of the present disclosure include applying the PVD-Al layer to the substrate to produce the reflective layer, transferring the mirror with the reflective layer to an ALD chamber of an ALD system, conducting atomic layer etching (ALE) to remove the aluminium oxides from the outer surface of the reflective layer to produce an etched surface of the reflective layer, and then depositing an ALD protective layer onto the etched surface of the reflective coating. The ALE process removes any metal oxides that may have formed on the outer surface of the aluminium of the reflective coating prior to depositing the ALD protective layer.

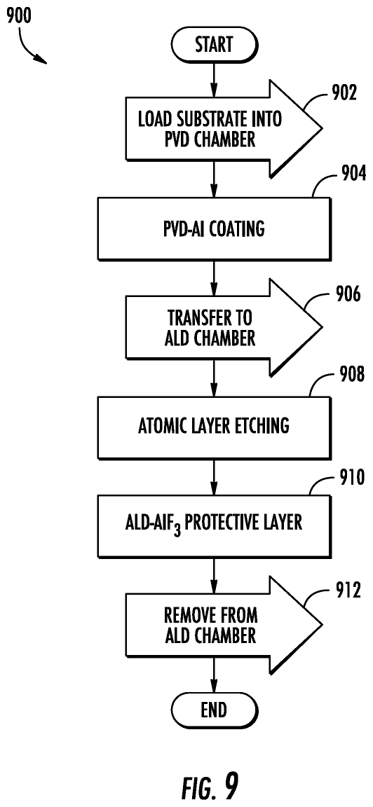

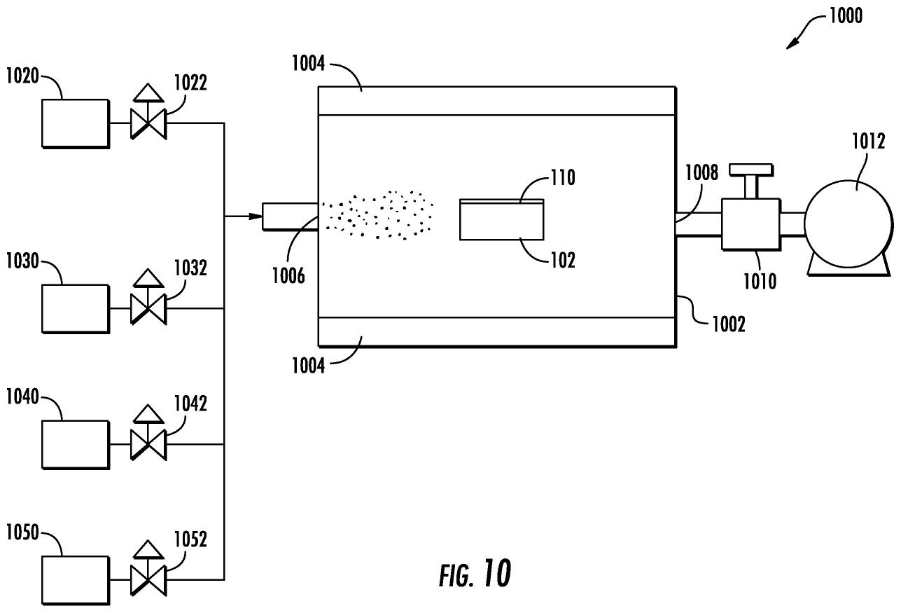

Referring now to FIG. 9, a flow chart of the method for producing the enhanced aluminium mirrors for VUV optics is schematically depicted. A substrate is first loaded into the PVD chamber of the PVD system, as indicated by step 902. In step 904, the PVD-Al layer is then deposited onto a mirror surface of the substrate to form the reflective coating comprising aluminium. The substrate having the PVD-Al reflective layer deposited thereon is then transferred to the ALD chamber of the ALD system, as indicated by step 906. During the transfer to the ALD chamber, the PVD-Al reflective layer can be exposed to air, which can cause some oxidation of the aluminium at the outer surface of the reflective layer. In step 908, an ALE process is conducted in the ALD system to remove material, such as aluminium oxides, from the surface of the reflective layer to produce an etched surface of the reflective layer. After the ALE process, the method includes depositing an ALD protective layer over the etched surface of the reflective layer in step 910 to produce the enhanced aluminium mirror. Following deposition of the ALD protective layer, the enhanced aluminium mirror can be removed from the ALD chamber, as indicated in Step 912. In some embodiments, step 912 may be followed by an optional ultraviolet radiation treatment. The ultraviolet radiation treatment is conducted at wavelengths in the optical region (e.g., between about 90 nm and about 1000 nm) and is preformed, for example, to remove any carbon molecules that may have accumulated on protective layer 120. Furthermore, in embodiments, the ultraviolet radiation treatment may be conducted for a duration of about 20 minutes or less, or about 15 minutes or less, or about 10 minutes or less, or from a range of about 5 minutes to about 20 minutes, or about 8 minutes to about 15 minutes. In some embodiments, the duration of the ultraviolet treatment is about 10 minutes.

Referring again to FIG. 2, one embodiment of the enhanced aluminium mirror 100 produced by the method 900 in FIG. 9 is schematically depicted. As previously discussed, the enhanced aluminium mirror 100 can comprise the substrate 102 comprising the reflective coating 110 deposited on the mirror surface 104 of the substrate 102. The reflective coating 110 can be the PVD-Al layer applied to the mirror surface 104 of the substrate 102 through the PVD process in step 904 of method 900 (FIG. 9). Referring again to FIG. 2, the enhanced aluminium mirror 100 can further include the ALD protective layer 120 deposited on the etched surface 122 of the reflective coating 110. The enhanced aluminium mirror 100 can include a very low concentration of oxygen in the reflective coating 110 and between the reflective coating 110 and the ALD protective layer 120.

The methods of the present disclosure enable the production of enhanced aluminium mirrors 100 for VUV optics that include a pin-hole free ALD protective layer 120 that reduces or prevents oxidation and degradation of the aluminium of the reflective coating 110 over time. The ALD coating process can enable all of the surfaces of the enhanced aluminium mirror to be coated in a single deposition run with atomic layer precision. In other words, ALD coating processes can enable conformal coating of all surfaces of the enhanced aluminium mirror 100 simultaneously, including non-mirror surfaces of the substrate. The ALD coating process can produce atomically dense, pin-hole-free protective films even at very small thickness, such as thicknesses down to a few nanometers, such as less than or equal to 10 nm. Thus, the ALD coating process can reduce the thickness of protective coatings to less than ⅕ the thickness of PVD-based protective coatings thick enough to provide the same protection. The ALD coating process can reduce coating stress and increase the lifetime of the enhanced aluminium mirrors.

Further, the methods disclosed herein also enable a PVD process to be used for applying the reflective coating 110 and an ALD process to be used to produce the ALD protective layer 120. In particular, the methods disclosed herein remove native aluminium oxides formed at the outer surface of the reflective coating 110 through an ALE process in the ALD chamber before the ALD protective layer is deposited. The strong reducing environment in the ALD chamber of the ALD system prevents further oxidation of the aluminium of the reflective coating 110 during the ALD process. Further, the ALE and ALD processes can be accomplished at similar temperatures, which can reduce delays between the ALE and ALD steps in the method and reduce the chances of further oxidation during heating or cooling steps. The ALE and ALD processes can be conducted using sulphur hexafluoride (SF₆) and/or SF₆ plasmas, which are better alternatives to hydrogen fluoride-based fluorine sources. Additionally, the ALD protective layer 120 can include a plurality of different layers comprising different metal fluoride materials. For instance, the ALD protective layer 120 can include an aluminium fluoride ALD layer and a magnesium fluoride ALD layer, which can reduce roughness and improve passivation of the enhanced aluminium mirror 100, among other features. In some embodiments, the ALD protective layer 120 comprises ALD-AlF₃—MgF₂.

Referring again to FIG. 8A, reference number 806 represents the reflection as a function of wavelength for the enhanced aluminium mirror 100 made according to the method 900 of FIG. 9. For the enhanced aluminium mirror represented by 806, the PVD-Al layer of the reflective coating was applied to a thickness of 100 nm. Following application of the PVD-Al layer, the mirror 100 was placed in the ALD chamber and the ALE process was conducted to remove 4 nm thickness of material from the outer surface of the reflective layer. Then, 4 nm of the ALD protective layer 120 comprising aluminium fluoride was applied to the etched surface according to the ALD coating methods disclosed herein. As shown in FIG. 8A, the enhanced aluminium mirror represented by reference number 806 exhibited greater reflection over the wavelength range of 150 nm to 180 nm compared to the mirrors represented by reference numbers 802 (PVD-only) and 804 (PVD-AL, low-density PVD-AlF₃, and ALD-AlF₃). It is noted that the method to make the enhanced mirror represented by 806 did not include the optional ultraviolet radiation treatment. The protective coating for the enhanced aluminium mirror represented by reference number 806 had an ALD protective layer of only 4 nm, while the mirror corresponding to reference number 802 had a PVD-AlF₃ protective layer with a thickness of 25 nm and the mirror corresponding to reference number 804 had a PVD-AlF₃ protective layer of 15 nm and an ALD-AlF₃ protective layer of 10 nm. Thus, the enhanced aluminium mirror made by the methods disclosed herein (ref. no. 806) can provide superior reflection performance and protection of the aluminium of the reflective coating while enabling a thinner thickness of the ALD protective layer compared to mirrors made by the conventional method 500 of FIG. 5 (ref. no. 802 in FIG. 8A) and the hybrid method 600 of FIG. 6 (ref. no. 804 in FIG. 8A).

FIG. 8B also depicts the reflection as a function of wavelength of an enhanced aluminium mirror made according to the method 900 of FIG. 9 but at shorter wavelengths than those depicted in FIG. 8A. In particular, the enhanced aluminium mirror represented by 806′ was prepared by applying a 100 nm thick layer of PVD-Al to substrate 102. Following application of the PVD-Al layer, the mirror 100 was placed in the ALD chamber and the ALE process was conducted to remove 4 nm thickness of material from the outer surface of the reflective layer. Then, 5 nm of the ALD protective layer 120 comprising aluminium fluoride was applied to the etched surface according to the ALD coating methods disclosed herein. It is noted that the method to make the enhanced mirror represented by 806′ did not include the optional ultraviolet radiation treatment. As shown in FIG. 8B, the enhanced aluminium mirror represented by 806′ exhibited greater reflection over the wavelength range of 100 nm to 160 nm compared to the mirror represented by reference number 802′ (PVD-only). In particular, the mirror represented by 802′ included a 100 nm PVD-Al reflective coating, a 10 nm low-density PVD-AlF₃ layer, and a 23 nm dense PVD-AlF₃ layer applied at 200° C.

FIG. 8C further depicts the aluminium mirrors of reference numerals 806′ and 802′ but with the inclusion of a 10 minute ultraviolet radiation treatment at optical wavelengths. In particular, the aluminium mirror of reference 806″ corresponds to 806′ but with the ultraviolet treatment, and the aluminium mirror of reference 802″ corresponds to 802′ but with the ultraviolet treatment. When comparing FIGS. 8B and 8C, the inclusion of the ultraviolet radiation treatment provided slightly higher reflection in the produced aluminium mirrors.

The first step in the methods for producing the enhanced aluminium mirrors 100 herein for VUV optics includes forming the reflective coating 110 on the mirror surface 104 of a substrate 102. Referring again to FIG. 2, the mirror 100 comprises a substrate 102, which provides a support structure for the reflective coating 110. The substrate 102 can include any substrate material having a rigid outer surface 104 capable of supporting the reflective coating 110 and is not particularly limited. The substrate 102 can be a metal, metal fluoride (e.g., CaF₂, MgF₂, etc.), metal alloy, metalloid, other suitable material, or combinations of materials. In embodiments, the substrate 102 can be aluminium metal, an aluminium alloy, silicon, CaF₂, MgF₂, or combinations of these.

The reflective coating 110 of the enhanced aluminium mirror 100 can be a PVD-Al layer applied to the mirror surface 104 of the substrate 102. The PVD-Al layer of the reflective coating 110 can be applied to the mirror surface 104 of the substrate 102 through a PVD process at ambient temperature according to known methods in the art. The reflective coating 110 comprising the PVD-AL layer can comprise aluminium metal. Referring to FIG. 2, the reflective coating 110 comprising the PVD-Al layer can have a thickness t_{AL} that is sufficient to ensure that the mirror surface 104 of the substrate 102 is completely covered with the PVD-Al layer and no portion of the substrate 102 on the mirror surface 104 is exposed. In embodiments, the reflective coating 110 comprising the PVD-Al layer can have a thickness t_{AL} that is greater than or equal to nm, greater than or equal to 80 nm, greater than or equal to 90 nm, or even greater than or equal to 100 nm. The reflective coating 110 comprising the PVD-Al layer can have a thickness t_{AL} of from 50 nm to 200 nm, such as from 70 nm to 200 nm, from 90 nm to 200 nm, from 100 nm to 200 nm, from 50 nm to 150 nm, from 70 nm to 150 nm, from 90 nm to 150 nm, from 100 nm to 150 nm, from 50 nm to 100 nm, or from 70 nm to 100.

Referring again to FIG. 9, following application of the PVD-Al layer, the substrate with the reflective coating is transferred from the PVD system to the ALD system, as indicated in step 906. As previously discussed, during transfer to the ALD system, the PVD-Al layer can come into contact with air or other oxidizing agents, which contact can cause oxidation of the aluminium at the outer surface of the PVD-Al layer to form aluminium oxides. To remove these aluminium oxides, the substrate with the reflective coating 110 is subjected to an ALE process in the ALD system to remove the layers of aluminium oxide formed through contact with the oxygen-containing atmospheres or other oxidizers. The ALE process in step 908 of FIG. 9 and deposition of the ALD protective layer in step 910 are both conducted in the ALD system.

Referring now to FIG. 10, one embodiment of an ALD system 1000 for conducting the ALE process and ALD processes is schematically depicted. The ALD system 1000 includes an ALD chamber 1002, which can be heated by one or a plurality of heating devices 1004 in thermal communication with the ALD chamber 1002. The ALD chamber 1002 has an inlet 1006 and an outlet 1008. The inlet 1006 is operable to introducing various constituents used in the ALD process or ALE process into the ALD chamber 1002. The outlet 1008 of the ALD chamber 1002 can be in fluid communication with a throttle valve 1010 disposed downstream of the ALD chamber 1002. Throttle valve 1010 can control the flow of gases and other materials out of the ALD chamber 1002. The ALD system 1000 can further include a vacuum pump 1012 disposed downstream of the throttle valve 1010. The vacuum pump 1012 can be operable to create a vacuum within the ALD chamber 1002 to assist in drawing ALD reaction constituents into the ALD chamber 1002 and pulling unreacted constituents, reaction products, inert gases, or other materials out of the ALD chamber 1002.

The ALD system 1000 can further include one or more sources of reaction constituents in fluid communication with the inlet 1006 of the ALD chamber 1002. In particular, the ALD system 1000 can include a fluorine source 1020, a metal precursor source 1030, an oxygen source 1040, or combinations of these. The ALD system 100 can include a fluorine source control valve 1022 disposed between the fluorine source 1020 and the ALD chamber 1002 and operable to control the flow rate of the fluorine source 1020 into the ALD chamber 1002. The ALD system 100 can include a metal precursor source control valve 1032 disposed between the metal precursor source 1030 and the ALD chamber 1002 and operable to control the flow rate of the metal precursor source 1030 into the ALD chamber 1002. The ALD system 100 can include an oxygen source control valve 1042 disposed between the oxygen source 1040 and the ALD chamber 1002 and operable to control the flow rate of the oxygen source 1040 into the ALD chamber 1002. The ALD system 1000 can also include an inert gas source 1050 and an inert gas control valve 1052 operable to control the flow of the inert gas from the inert gas source 1050 into the ALD chamber 1002. Prior to the ALE process, the substrate 102 comprising the reflective coating 110 is placed within the ALD chamber 1002 of the ALD system 1000.

Referring again to FIG. 2, as previously discussed, the methods of making the mirror 100 disclosed herein include removing aluminium oxides from the outer surface 112 of the aluminium reflective coating 110 by conducting an ALE process in the ALD system 1000 to produce an etched surface 122 of the reflective coating 110. The ALE process includes exposing the reflective coating 110 to alternating pulses of a fluorine source and an organometallic compound. The substrate 102 and reflective coating 110 can be contacted with or exposed to the alternating pulses of the fluorine source and organometallic compounds at operating conditions sufficient to cause the fluorine source, the organometallic compounds, or both to undergo chemical reactions at the surfaces of the substrate 102, reflective coating 110, or both. The methods disclosed herein can include exposing the reflective coating 110 to alternating pulses of the fluorine source and the organometallic source at an ALE temperature of from 150° C. to 325° C., from 150° C. to 300° C., from 150° C. to 250° C., from 200° C. to 325° C., from 200° C. to 300° C., or even from 200° C. to 250° C. At ALE temperatures less than about 150° C., the etching rate may be too low. At temperatures greater than about 325° C., the higher temperatures may cause other quality defects, such as thermal changes to the substrate 102 or the aluminium of the reflective layer 110. The methods disclosed herein can include exposing the aluminium layer to pulses comprising the fluorine source, the pulses comprising the organometallic source, or both at from 50 Watts (W) to 600 W, or even from 100 W to 300 W.

Exposing the reflective coating 110 to the pulse comprising the fluorine source converts aluminium oxides at the outer surface of the reflective coating 110 to aluminium fluoride to form a thin layer of aluminium fluoride on the outer surface of the reflective coating 110. Some aluminium metal can also react with the fluorine source to produce aluminium fluorides at the outer surface 112 of the reflective coating 110. The layer of aluminium fluoride at the outer surface 112 of the reflective coating 110 can be a single molecule in thickness. The oxygen that is replaced can form one or more volatile oxygen species that are released into the ALD chamber 1002. Following the pulse containing the fluorine source, the ALD chamber 1002 can be purged with an inert gas (e.g., Ar, He, Ne, etc.) to remove the volatile oxygen species and any residual fluorine source from the ALD chamber 1002 prior to performing the next pulse of the organometallic compound.

After purging, the methods include exposing the thin layer of aluminium fluoride to a pulse comprising the organometallic compound. Exposing the aluminium fluoride layer to the organometallic compound can cause the aluminium fluoride to react to form volatile organometallic fluoride compounds that are released from the outer surface 112 of the reflective coating 110 and out into the ALD chamber 1002. Referring again to FIG. 10, organometallic compound can be introduced from the metal precursor source 1030 of the ALD system 1000 or by a separate organometallic compound source (not shown). Exposing the aluminium fluoride layer to the organometallic compound can include introducing the organometallic compound into the ALD chamber 1002 and then closing the throttle valve 1010 to seal up the ALD chamber for a duration of time sufficient for all the AlF₃ to react with the organometallic compound. The volatile organometallic fluoride compound and any remaining unreacted organometallic compounds can be removed from the ALD chamber 1002 by purging the ALD chamber 1002 with an inert gas after the reaction is complete.

Each iteration of the ALE process removes about a single molecular layer of aluminium oxide from the surface of the reflective coating 110. The ALE process (e.g., the alternating pulses of the fluorine source and organometallic compound) can be repeated a plurality of times until the aluminium oxides are all removed or to a target depth of from 1 nm to 10 nm, or from 3 nm to 5 nm, from the original outer surface 112 of the reflective layer 110 prior to ALE. In other words, the ALE process can be repeated until from 1 nm to 10 nm or from 3 nm to 5 nm of the material is removed from the outer surface 112 of the reflective layer 110 to produce the etched surface 122 of the reflective layer 110. Following the ALE process, the reflective coating 110 can be substantially free of oxygen containing compounds.

The fluorine source can be derived from a fluorine-containing precursor. The fluorine-containing precursor can be selected from the group consisting of sulfur hexafluoride (SF₆), nitrogen trifluoride (NF₃), trifluoroiodomethane (CF₃I), hydrogen fluoride (HF), and combinations of these. In embodiments, the fluorine source can be a plasma fluorine source derived from a fluorine-containing precursor or a fluorine-containing precursor and argon (Ar) plasma. In embodiments, the fluorine source may be a plasma comprising SF₆, SF₆ and Ar (SF₆/Ar), or NF₃ and Ar (NF₃/Ar).

HF is commonly used as a fluorine source in ALD systems. However, using HF as the fluorine source requires increasing the temperature of the ALD chamber 1002 in order to promote reduction of the aluminium oxides to form AlF₃. The substrate 102 and reflective layer 110 must then be cooled to a lower temperature for the ALD process. Oxidation of the etched surface 122 during this cool down period is a concern that could reduce the effectiveness of removal of the aluminium oxides during the ALE process on the reflectance of the enhanced aluminium mirror 100. Additionally, HF is dangerous to handle and highly corrosive, particularly when contacted with water. Thus, in embodiments, the fluorine source can be a non-HF fluorine source that enables the same process temperature for both ALE and ALD processes and that is significantly safer.

SF₆ fluorine precursor is significantly safer to use compared to HF and enables similar temperature ranges to be used for both the ALE and ALD processes. In embodiments, the fluorine source may comprise SF₆ or a plasma derived from SF₆ (i.e., SF₆-based plasma). In embodiments, the fluorine source may comprise, consist of, or consist essentially of an SF₆-based fluorine source, such as SF₆ or an SF₆-based plasma. In embodiments, the fluorine source may comprise, consist of, or consist essentially of a plasma derived from SF₆ and Ar (i.e., SF₆/Ar plasma) or SF₆ and other inert gases. When the fluorine source comprises an SF₆/Ar plasma, a flow rate ratio of the Ar to SF₆ may be from 0.1:1 to 10:1, from 0.1:1 to 5:1, from 0.1:1 to 2:1, from 0.5:1 to 10:1, from 0.5:1 to 5:1, from 0.5:1 to 2:1, from 1:1 to 10:1, from 1:1 to 5:1, from 1:1 to 2:1, from 2:1 to 10:1, from 2:1 to 5:1, or about 2:1, where flow rate is a volumetric flow rate expressed in units of sccm (standard cubic centimeters per minute).

The fluorine source may be converted into a plasma by heating a fluorine precursor, such as but not limited to SF₆, and subjecting the heated fluorine precursor to an electric current or a strong electromagnetic field. Argon (Ar) can be added to create an SF₆/Ar plasma. The materials (e.g., fluorine precursor, Ar, or combinations of these) can be heated to the ALD process temperature and subjected to an electric current sufficient to convert the materials into a plasma. In embodiments, converting the materials (e.g., fluorine precursor, Ar, or combinations of these) into a plasma may comprise heating the materials to a temperature of from 100° C. to 325° C., or from 120° C. to 250° C., and applying an electric current having a power of from 50 Watts (W) to 600 W, or from 100 Watts (W) to 300 W.

The methods may include exposing the reflective coating 110 comprising the PVD-Al layer to the pulse comprising the fluorine source at the ALE temperature of from 150° C. to 325° C., such as from 200° C. to 250° C. The methods can include exposing the reflective coating 110 comprising the PVD-Al layer to the pulse comprising the fluorine source at a power of from 50 W to 600 W, from 50 W to 300 W, from 100 W to 600 W, or even from 100 W to 300 W. The methods can include exposing the reflective coating 110 comprising the PVD-Al layer to the pulse comprising the fluorine source for a fluorine pulse duration that is sufficient to react all the aluminium oxide molecules on the very outer surface of the PVD-Al layer with the fluorine source to produce a single molecule layer of aluminium fluoride. In embodiments, the fluorine pulse duration can be from 1 second to 30 seconds, or about 7 seconds. As previously discussed, after exposing the outer surface of the reflective layer 110 to the fluorine source for the exposure time, the ALD chamber can be purged with an inert gas for a purge time sufficient to remove at least 99% of the residual fluorine source and oxides from the ALD chamber.

Following exposure to the fluorine source and purging, the ALE process can include exposing the aluminium fluoride layer to a pulse comprising the organometallic compound. The organometallic compound can include one or more of trimethylaluminium (TMA), triethylaluminium (TEA), dimethylaluminium chloride (DMAC), silicon tetrachloride (SiCl₄), aluminium hexafluoroacetylacetonate (Al(hfac)₃), Tri-i-butylaluminium (Al(iBu)₃), tin(II) acetylacetonate (Sn(acac)₂), tris(2,2,6,6-tetramethyl-3,5-heptanedionato)aluminium (i.e., Al(TMHD)₃, or combinations of these. In embodiments, the organometallic compound can be an organoaluminium compound selected from the group consisting of TMA, YEA, DMAC, aluminium hexafluoroacetylacetonate, Tri-i-butylaluminium (Al(iBu)₃), tris(2,2,6,6-tetramethyl-3,5-heptanedionato)aluminium (i.e., Al(TMHD)₃, and combinations of these. In embodiments, the organometallic compound can be TMA, and exposure of the thin layer of aluminium fluoride on the surface of the reflective layer to the TMA causes reaction between the TMA and the aluminium fluoride to form AlF(CH₃)₂ gas. The AlF(CH₃)₂ is released from the outer surface of the reflective coating 110 and into the ALD chamber.

Referring again to FIG. 10, in embodiments, exposing the thin layer of aluminium fluoride to the pulse comprising the organometallic compound can include injecting the organometallic compound into the ALD chamber 1002 for a pulse length and closing the throttle valve 1010 of the ALD system 1000 for a shut in period. Closing the throttle valve 1010 prevents flow of material into or out of the ALD chamber 1002 and maintains the thin layer of aluminium fluoride in contact with the organometallic compound for the shut in period. The pulse length can be sufficient to introduce a target amount of the organometallic compound into the ALD chamber 1002. In embodiments, the pulse length can be from about 10 ms to about 5000 ms, such as from about 300 ms to about 700 ms, or about 400 ms. Once the throttle valve 1010 is closed, the thin layer of aluminium fluoride can be contacted with the organometallic compound for the shut-in period, which is sufficient for the organometallic compound to react with all of the aluminium fluoride to convert the aluminium fluoride to the volatile organometallic compounds. In embodiments, the total contact time of the thin layer of aluminium fluoride and the organometallic compounds can be from about 10 milliseconds (ms) to about 60,000 ms (60 seconds), or from about 10 ms to about 30 seconds, where the total contact time of the thin layer of aluminium fluoride and the organometallic compounds includes the pulse length and the shut-in period. In embodiments, the ALE process can include injecting the organometallic compound into the ALD chamber 1002 for a pulse length of from about 10 ms to about 5,000 ms, such as from about 300 ms to about 700 ms, closing the throttle valve 1010, and maintaining contact of the organometallic compound with the thin layer of aluminium fluoride for a shut-in period of from about 1 second to about 60 seconds or from about 10 seconds to about 30 seconds.

The method may include exposing the thin layer of aluminium fluoride to the organometallic compound at a temperature and pressure sufficient for the organometallic compound to react with the aluminium fluoride to produce the volatile organometallic compound. In embodiments, the method can include exposing the thin layer of aluminium fluoride to the organometallic compound at the ALE temperature of from 150° C. to 325° C. The method may include exposing the thin layer of aluminium fluoride to the organometallic compound at a pressure of from 10 millitorr (1.33 Pa) to 100 torr (13,332 Pa).

Referring again to FIG. 10, following the shut-in period, the ALE process can include re-opening the throttle valve and evacuating the atmosphere from the ALD chamber 1002 to remove the volatile organometallic compounds and any residual vaporous species from the ALD chamber 1002. In embodiments, the ALE process can further include purging the ALD chamber 1002 with inert gas to remove at least 99% of the residual organometallic compounds, the volatile aluminium compounds, or both from the ALD chamber.

The ALE steps of exposing the outer surface 112 of the reflective layer 110 to the pulse comprising the fluorine source to produce the thin layer of aluminium fluoride, purging, contacting the thin layer of aluminium fluoride with the organometallic compound to convert the aluminium fluoride to a volatile organometallic compound, and purging can be performed a plurality of times. The etch rate of the ALE process can be about 1.1 Angstroms of thickness per cycle (A/cycle) at an ALE temperature of 225° C. One complete cycle of the ALE process comprises one pulse of the fluorine source and one pulse of the organometallic compound with the accompanying purge steps therebetween. The ALE process can be continued for a plurality of cycles necessary to remove all of the aluminium oxides from the surface of the reflective coating.

Referring again to FIG. 2, the result of the ALE process is the substrate 102 having the reflective coating 110 with an etched surface 122 and no intervening aluminium oxide layer disposed on top of the reflective coating 110. In embodiments, the etched surface 122 of the reflective coating 110 can be substantially free of metal oxides. In embodiments, an amount of oxygen at an interface between the etched surface 122 of the reflective layer 110 and the ALD protective layer 120 is less than or equal to an amount of oxygen in the aluminium of the reflective layer 110.

Following the ALE process to etch away the aluminium oxides from the surface of the reflective layer 110, the ALD protective layer 120 is then deposited on top of the etched surface 122 of the reflective coating 110. The ALD protective layer 120 and ALD process for producing the ALD protective layer 120 will now be described with reference to the enhanced aluminium mirror 100 in FIG. 2 and the ALD system 1000 depicted in FIG. 10. Referring now to FIG. 2, the enhanced aluminium mirror 100 comprises one or more ALD protective layers 120 deposited onto the etched surface 122 of the reflective coating 110 so that the ALD protective layer 120 is in contact with the etched surface 122 of the reflective coating 110. In embodiments, the ALD protective layer 120 may provide a barrier on the etched surface 122 of the reflective coating 110 that reduces or prevents oxidizing compounds from contacting the aluminium of the reflective coating 110, thereby reducing or prevent oxidation of the aluminium to form aluminium oxides. As previously discussed, reducing and/or preventing formation of aluminium oxides on the surfaces of the enhanced aluminium mirror 100 can improve the reflectance and service life of the enhanced aluminium mirror 100 compared to PVD-only aluminium mirrors or aluminium mirrors having a hybrid protective coating comprising a PVD component and an ALD component. The ALD protective layer 120 may also be deposited on other surfaces of the substrate that do not have the reflective coating 110 deposited thereon.

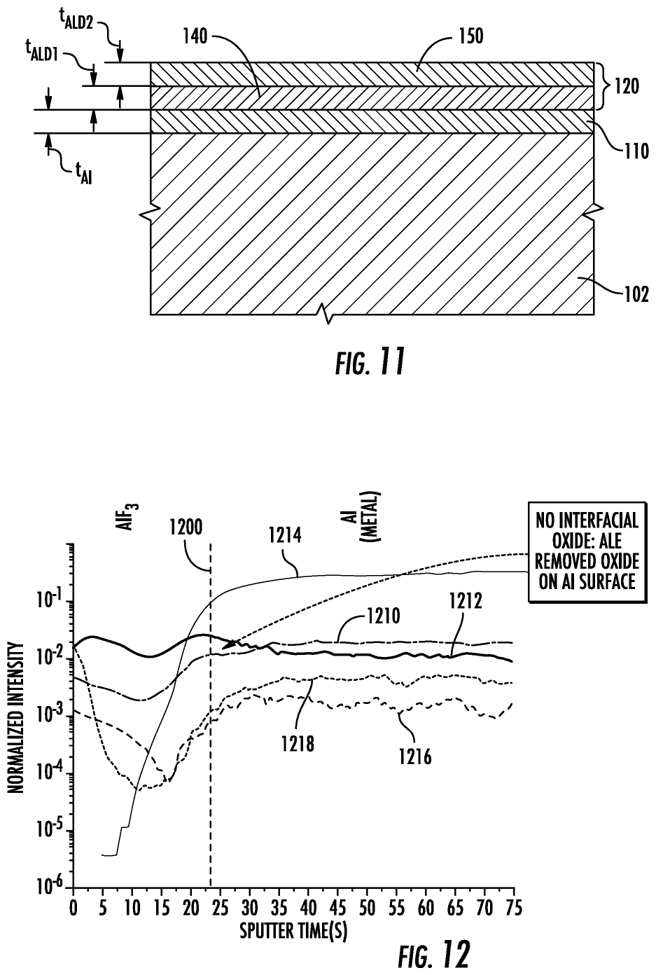

The ALD protective layer 120 can comprise a metal fluoride. In embodiments, the ALD protective layer 120 can be aluminium fluoride (AlF₃), magnesium fluoride (MgF₂), lithium fluoride (LiF), calcium fluoride (CaF₂), or combinations thereof. Additionally or alternatively, in embodiments, the ALD protective layer 120 may comprise other metal fluorides, such as but not limited to, lanthanum fluoride (LaF₃) ALD coatings or gadolinium fluoride (GdF₃) ALD coatings. In some embodiments, the ALD protective layer 120 comprises AlF₃ and MgF₂. The ALD protective layer 120 can be coupled directly to the etched surface 122 of the reflective coating 110. As used herein, the term “coupled directly to” means that the ALD protective layer 120 contacts and is bonded to the etched surface of the reflective coating 110 without any intervening coating or layer disposed between the ALD protective layer 120 and the etched surface 122 of the reflective coating 110. Referring now to FIG. 11, the enhanced aluminium mirror 100 can include an ALD protective layer 120 that comprises a plurality of ALD coating layers (e.g., first ALD coating layer 140, second ALD coating layer 150, etc.) applied to the reflective coating 110 of the enhanced aluminium mirror 100.

Referring again to FIG. 2, the ALD protective layer 120 can be applied to the etched surface 122 of the reflective coating 110 by the ALD process. During the ALD process, the substrate 102 comprising the reflective coating 110 thereon is exposed to alternating pulses of one or more precursor compounds, where exposure to the alternating pulses of the precursor compounds causes layer-by-layer deposition of the ALD protective layer 120 on the etched surface 122 of the reflective coating 110 and, optionally, on other non-reflective surfaces of the substrate 102. Each deposited layer during one cycle of the ALD process can have a thickness comparable to a size of a single molecule of the ALD coating material (e.g. monolayer coverage of the surface(s)). The ALD process can enable coating all the surfaces of the substrate 102 in a single deposition run with atomic layer precision. The alternating pulses can include a metal precursor pulse and a fluorine source pulse. In embodiments, the ALD process can include a first pulse comprising a metal precursor, a second pulse comprising an oxygen source, and a third pulse comprising a fluorine source.

In embodiments, the ALD process may be a direct reduction ALD process, during which the metal precursor is deposited onto the etched surface 122 of the reflective coating 110 or other surfaces of the substrate 102 and then directly reduced using a reducing agent, such as the fluorine source, to produce the ALD protective layer 120. In embodiments, the ALD process for applying the ALD protective layer 120 may include exposing at least the etched surface 122 of the reflective coating 110 to alternating pulses of a metal precursor and a fluorine source. Referring to FIG. 10, exposing the etched surface of the reflective coating to the alternating pulses of the metal precursor and fluorine source can be conducted in the ALD chamber 1002 of the ALD system 1000. The pulse of the metal precursor may include the metal precursor. In some embodiments, the pulse of the metal precursor may include the metal precursor and one or more inert gases. Inert gases may include non-reactive gases, such as but not limited to noble gases (e.g., Ar, He, Ne, etc.). The inert gas may act as a carrier for transporting the precursors into the ALD chamber. The pulse of each of the metal precursor and the fluorine source may be of sufficient time duration to enable the metal precursor and fluorine source, during their respective pulses, to react with at least 90%, at least 95%, at least 98%, at least 99%, or even at least 99.9% of the reaction sites at the etched surface 122 of the reflective coating 110 or outer surfaces of the previously applied metal precursor or ALD protective layer. Between injection of each pulse of metal precursor and fluorine source, the ALD chamber 1002 may be purged with an inert gas (e.g., Ar, He, Ne, etc.) to remove any residual metal precursor and/or fluorine source prior to the next pulse.

The process for deposing the ALD protective layer 120 has a similar chemistry to the ALE process, except that the order of the steps is in reverse. In the ALD process, the reflective coating 110 is exposed to the metal precursor pulse first, followed by exposure to the fluorine source pulse. For the ALD process, the duration of exposure to the metal precursor pulse is much less compared to the total contact time between the organometallic compound and the aluminium fluoride in the ALE process. Additionally, in the ALD process, the throttle valve 1010 of the ALD system 1000 (FIG. 10) remains open during the pulse of the metal precursor. The ALD process can be operated at the same temperature as the ALE process.

In embodiments, the ALD protective layer 120 can be a metal fluoride coating, and the ALD process can include exposing the etched surface 122 of the reflective coating 110 to the pulse containing the metal precursor, purging the ALD chamber after the metal precursor pulse with an inert gas, and exposing the etched surface 122 of the reflective coating 110 to a subsequent pulse of the fluorine source. During the pulse of the metal precursor, the metal precursor, in vapour, plasma, or atomized liquid form, may be injected into the ALD chamber containing the substrate 102 with the reflective coating 110 that has been etched through the ALE process. The ALD process may further include heating the metal precursor (e.g., aluminium precursor, magnesium precursor, lithium precursor, calcium precursor, lanthanum precursor, gadolinium precursor, etc.) to a temperature greater than or equal to 95° C. prior to introducing the metal precursor to the ALD chamber. Exposing the etched surface 122 of the reflective coating 110 to the pulse containing the metal precursor may cause the metal precursor to react with the aluminium at the etched surface 122 of the reflective coating 110 to bond a single layer of ligated metal onto the etched surface 122 of the reflective coating 110.

The single layer of ligated metal bonded to the surface may have a thickness approximately equal to a size of a single molecule of the ligated metal. For pulses of the metal precursor subsequent to depositing the initial ALD metal fluoride layer directly bonded to the etched surface 122, the metal precursor may react with the previously deposited metal fluoride to bond a subsequent single layer of ligated metal to the outer surface of the previously deposited ALD metal fluoride layer. After depositing and bonding the single layer of ligated metal to the surface (e.g., etched surface 122 or surface of previously deposited ALD metal fluoride layer), the ALD process may further include ceasing exposure of the mirror to the metal precursor. Ceasing exposure of the mirror to the metal precursor may include stopping the flow of the metal precursor into the ALD chamber.

The pulse of the metal precursor may have a pulse duration sufficient for the metal precursor to react with at least 90%, at least 95%, at least 98%, at least 99%, or at least 99.9% of the reactive aluminium sites at the etched surface 122 of the reflective coating 110 or of the reactive metal fluoride sites at the outer surface of the previous applied ALD metal fluoride layer. In embodiments, the pulse of the metal precursor may have a pulse duration of from 10 milliseconds (ms) to 10 seconds (s), or for about 1 second. Factors influencing the pulse duration include the vapor pressure of the metal precursor, flow rate of the metal precursor, reactivity of the metal precursor with the surface, volume of the ALD chamber, and dimensions of the substrate 102. In embodiments, the pulse duration of the metal precursor can be set to achieve coverage, preferably conformal coverage, of at least 90%, or at least 95%, or at least 98%, or at least 99%, or at least 99.9% of the area of the etched surface 122 of the reflective coating 110 and optionally all of the other surfaces of the substrate 102. Referring again to FIG. 10, during the pulse of the metal precursor in the ALD process, the throttle valve 1010 is maintained in the open position. The ALD chamber then may be purged with an inert gas to remove any residual metal precursor from the ALD chamber before continuing with the ALD process.

After purging the chamber, the mirror may be exposed to the pulse comprising the fluorine source. During the fluorine source pulse, the fluorine source may be injected into the ALD chamber containing the mirror. The fluorine source pulse may include the fluorine source or the fluorine source in combination with an inert gas, such as any of the inert gases discussed herein. Exposing the layer of ligated metal bonded to the surfaces of the mirror to the subsequent pulse containing the fluorine source may cause the fluorine source to react with the ligated metal to reduce the ligated metal to form the metal fluoride (e.g., undergo a chemical reduction reaction between the fluorine source and ligated metal to replace the ligand with fluorine to produce the metal fluoride of the ALD protective layer 120). Injection of the fluorine source may be ceased at the end of the pulse, when at least 90%, at least 95%, at least 98%, at least 99%, or even at least 99.9% of the ligated metal at the surface of the mirror has reacted with the fluorine source to form the metal fluoride. In embodiments, the fluorine source pulse may have a pulse duration of from 10 ms to 30 s, such as from 10 ms to 20 s, from 10 ms to 10 s, from 1 s to 30 s, from 1 s to 20 s, from 1 s to 10 s, from 3 s to 30 s, from 3 s to 20 s, or from 3 s to 10 s. The fluorine source pulse may be ceased by stopping the flow of the fluorine source into the ALD chamber. The ALD process may be repeated a plurality of times through a sequence of alternating pulses of metal precursor and fluorine source to add further ALD metal fluoride layers to increase the thickness of the ALD protective layer 120.

In embodiments, the ALD protective layer 120 can include an ALD aluminium fluoride (ALD-AlF₃) layer. When the ALD protective layer 120 includes an ALD-AlF₃ layer, the metal precursor can be a metal ligand complex comprising aluminium. In embodiments, the metal precursor may can include one or more of TMA, TEA, dimethylaluminium isopropoxide (DMAI), dimethylaluminium hydride: dimethylethylamine, ethylpiperidine:dimethylaluminium hydride, dimethylaluminium chloride (DMAC), aluminium hexafluoroacetylacetonate (Al(hfac)₃), tri-i-butylaluminium (Al(i-Bu)₃), tris(2,2,6,6-tetramethyl-3,5-heptanedionato)aluminium (Al(TMHD)₃, or combinations thereof. Other aluminium compounds may also be suitable for use as the metal precursor. In embodiments, the ALD protective layer 120 can include an ALD magnesium fluoride (ALD-MgF₂) layer. In the case of an ALD-MgF₂ layer, the metal precursor may be a metal ligand complex comprising magnesium as the metal. In embodiments, the metal precursor may be selected from the group consisting of bis(ethylcyclopentadienyl)magnesium, bis(cyclopentadienyl)magnesium(II), bis(2,2,6,6-tetramethyl-3,5-heptanedionato)magnesium, bis(N,N′-di-sec-butylacetamidinato)magnesium, bis(pentamethylcyclopentadienyl)magnesium, and combinations of these. Other magnesium-containing compounds may also be suitable as the metal precursor for forming the MgF₂ ALD layer.

In embodiments, the ALD protective layer 120 can be a metal fluoride having a metal other than aluminium or magnesium. In these cases, similar metal ligand complexes may be used where the metal is different from aluminium or magnesium. For instance, in embodiments, the metal of the metal precursor may be calcium (Ca), lithium (Li), or combinations thereof. In embodiments, the ALD protective layer 120 can include an ALD calcium fluoride (ALD-CaF₂) layer. When the ALD protective layer 120 is an ALD-CaF₂ layer, the metal precursor may be selected from the group consisting of Ca(2,2,6,6-tetramethyl-3,5-heptanedionato)₂, Bis(N,N′-diisopropylformamidinato)calcium(II), bis(N,N′-diisopropylacetamidinato)calcium(II), [Ca₃(2,2,6,6-tetramethyl-3,5-heptanedionate)₆], Ca(1,2,4-triisopropylcyclopentadienyl)₂], and combinations thereof. In embodiments, the ALD protective layer 120 can include an ALD lithium fluoride (ALD-LiF) coating. When the ALD protective layer 120 includes the ALD-LiF layer, the metal precursor may be selected from the group consisting of lithium tert-butoxide, lithium 2,2,6,6-tetramethyl-3,5-heptanedionate, and combinations thereof.

In embodiments, the ALD protective layer 120 can include a high reflective index fluoride ALD layer, such as but not limited to lanthanum fluoride (LaF₃), gadolinium fluoride (GdF₃), or combinations of these. When the ALD protective layer 120 includes the ALD-LaF₃ layer, the metal precursor can be one or more lanthanum precursors selected from the group consisting of tris(N,N′-diisopropylformamidinato) lanthanum, tris [N,N-bis(trimethylsilyl)amide]lanthanum(III), (2,2,6,6-tetramethyl-3,5-heptanedione) lanthanum, tris(tetramethylcyclopentadienyl) lanthanum(III), LANA™ brand lanthanum precursor from Air Liquide, and combinations thereof. When the ALD protective layer 120 includes the ALD-GdF₃ layer, the metal precursor can be one or more gadolinium precursors selected from the group consisting of gadolinium tris(N,N′-isopropylacetamidinate), tris(isopropyl-cyclopentadienyl) gadolinium(III) (Gd(iPrCp)₃), tris(OCMe₂CH₂OMe) gadolinium(III) (Gd(mmp)₃), tris(2,3-dimethyl-2-butoxy) gadolinium(III) (Gd(DMB)₃), tris(2,2,6,6-tetramethyl-3,5-heptanedionato) gadolinium(III) (Gd(thd)₃), GANBETTA™ brand gadolinium precursor available from Air Liquide, GAUDI™ brand gadolinium precursor available from Air Liquide, and combinations thereof.

The metal precursor may be in vapor, plasma, liquid, or atomized liquid form. The metal precursor pulse may include the metal precursor or a mixture of the metal precursor and an inert gas, which may be any of the inert gases previously discussed herein. The inert gas may be used as a carrier gas to transport the metal precursor into the ALD chamber.

In embodiments, the ALD protective layer 120 may be a metal fluoride compound comprising a plurality of different metals. In embodiments, the ALD protective layer 120 may have the general formula A_{X}M_{Y}F_{Z}; where A is a first metal selected from the group consisting of Mg, Ca, Li, and Al; M is a second metal different from the first metal A, where M is selected from the group consisting of Mg, Ca, Li, and Al; X is the number of moles of the first metal A; Y is the number of moles of the second metal M; and Y is the number of moles of fluorine (F). In embodiments, the ALD protective layer 120 may be Li_{X}Al_{Y}F_{Z} or Ca_{X}Al_{Y}F_{Z}, in which X is the number of moles of Li or Ca, respectively; Y is the number of moles of Al, and Z is the number of moles of F. Other metal fluorides comprising a mixture of different metals are contemplated. Metal fluoride ALD coatings comprising a plurality of different metals may be made by exposing the optical component to a metal precursor pulse having a plurality of different metal precursors, each of the different metal precursors having a different metal.

The fluorine source can be derived from a fluorine-containing precursor selected from the group consisting of sulfur hexafluoride (SF₆), nitrogen trifluoride (NF₃), ammonium fluoride (NH₄F), trifluoroiodomethane (CF₃I), hydrogen fluoride (HF), and combinations thereof. In embodiments, the ALD process can be a plasma-assisted ALD process in which the fluorine source is a plasma fluorine source derived from a fluorine-containing precursor or a fluorine-containing precursor and argon (Ar) plasma. In embodiments, the fluorine source can be a plasma comprising SF₆, SF₆ and Ar (SF₆/Ar), or NF₃ and Ar (NF₃/Ar). In embodiments, the fluorine source can be derived from one or more organic fluorine sources, such as but not limited to hexafluoroacetylacetone or other fluorine-containing organic compounds. However, organic fluorine sources may require additional pulse steps in the ALD process, such as a long ozone pulse, to remove the carbon compounds, which are contributed by the organic fluorine source, from the ALD coating.

HF is commonly used as a fluorine source in ALD coating operations. However, HF is dangerous to handle and highly corrosive, particularly when contacted with water. Therefore, safer alternatives to HF are desired. SF₆ fluorine precursor is significantly safer to use compared to HF and is more productive than organic fluorine sources, which require a four-step process and a long ozone pulse to form the metal fluoride ALD protective layer. In embodiments, the fluorine source may comprise SF₆ or a plasma derived from SF₆ (i.e., SF₆-based plasma). In embodiments, the fluorine source may comprise, consist of, or consist essentially of an SF₆-based fluorine source, such as SF₆ or an SF₆-based plasma. In embodiments, the fluorine source may comprise, consist of, or consist essentially of a plasma derived from SF₆ and Ar (i.e., SF₆/Ar plasma) or SF₆ and other inert gas. When the fluorine source comprises an SF₆/Ar plasma, a flow rate ratio of the Ar to SF₆ may be from 0.1:1 to 10:1, from 0.1:1 to 5:1, from 0.1:1 to 2:1, from 0.5:1 to 10:1, from 0.5:1 to 5:1, from 0.5:1 to 2:1, from 1:1 to 10:1, from 1:1 to 5:1, from 1:1 to 2:1, from 2:1 to 10:1, from 2:1 to 5:1, or about 2:1, where flow rate is a volumetric flow rate expressed in units of sccm (standard cubic centimeters per minute).

As previously discussed, the ALD process can be a direct reduction process in which deposition of the ALD protective layer 120 is accomplished by bonding the ligated metal to the surface of the optical component and then directly reducing the ligated metal with the fluorine source to produce the ALD metal fluoride layer. However, when SF₆, SF₆ plasma, or SF₆/Ar plasma is used as the fluorine source, the resulting ALD coating can have a high concentration of carbon impurities originating from the ligands of the ligated metal. Not intending to be bound by any particular theory, it is believed that the sulphur from the SF₆ may react with the ligands to damage or break apart the ligands during the reaction of the ligated metal with the fluorine source to produce the metal fluoride, thus, causing carbon or carbon-containing fragments of the ligands to remain in the ALD protective layer.

When SF₆ is used to provide the fluorine source, the concentration of carbon deposits in the ALD protective layer 120 can be reduced or eliminated by conducting an oxide formation step between the metal precursor pulse and the fluorine source pulse. The oxide formation step can include exposing the mirror having the layer of ligated metal deposited on the surfaces thereof to an oxygen source for a pulse duration sufficient to oxidize or convert the ligated metal to a metal oxide. Exposure of the ligated metal to the pulse containing the oxygen source may cause the ligand of the ligated metal to react with oxygen of the oxygen source to replace the ligand with oxygen, which becomes bonded to the metal (e.g., the ligated metal undergoes an oxidation reaction to convert the ligated metal layer into a metal oxide layer). Following the metal oxide formation, the ALD chamber may be purged of any residual oxygen source. The mirror with the layer of metal oxide on the outermost surfaces can then be exposed to the pulse containing the fluorine source. Exposure of the metal oxides to the fluorine source converts the metal oxide into the metal fluoride of the ALD protective layer 120. The oxygen source can include water (H₂O), H₂O plasma, ozone (O₃), O₃ plasma, oxygen (O₂), O₂ plasma, hydrogen peroxide, other oxygen-containing gases, other oxygen-containing liquids, or combinations thereof. The oxygen source can be in a liquid state, gaseous state, or plasma state. In embodiments, the oxygen source pulse can include the oxygen source or the oxygen source in combination with one or more inert gases, which may be any of the inert gases previously described herein.

When an SF₆-based fluorine source is used, the ALD process comprising first converting the metal ligand to the metal oxide with the oxygen source pulse and then converting the metal oxide to metal fluoride with the fluorine source pulse may produce an ALD protective layer having a lesser concentration of carbon compared to direct reduction of the metal ligand with the fluorine source. Not intending to be bound by any particular theory, it is believed that oxidation of the ligands of the ligated metal may wholly remove the ligands from the metal without decomposing the ligand, thereby eliminating or greatly reducing the fragments of organic (carbon-containing) constituents that remain attached to the metal or that otherwise remain present in the ALD protective layer 120.

In embodiments, the methods disclosed herein can include exposing the etched surface 122 of the reflective layer 110 of the mirror to the pulse containing the metal precursor to produce a metal ligand layer, exposing the metal ligand layer a pulse containing an oxygen source to produce a metal oxide layer, and then exposing the metal oxide layer to the pulse containing the fluorine source to convert the metal oxides to the metal fluoride of the ALD protective layer 120. The ALD process of the methods disclosed herein can first comprise exposing the mirror to the metal precursor. During the pulse of the metal precursor, the metal precursor, in vapour, plasma, or atomized liquid form, can be introduced, such as through injection, into the ALD chamber containing the mirror (i.e., substrate 102 comprising the reflective layer 110 after atomic layer etching). Exposing the surfaces of the mirror to the pulse containing the metal precursor may cause the metal precursor to react with the aluminium at the etched surface 122 of the reflective coating 110 of the mirror to bond a single layer (monolayer) of ligated metal onto the etched surface 122 of the reflective coating 110. The metal precursor may be any of the metal precursors previously described herein. The metal precursor pulse may have a duration sufficient to cause the metal precursor to react with at least 90%, at least 95%, at least 98%, at least 99%, or even at least 99.9% of the reactive aluminium sites on the etched surface 122 of the reflective layer 110. The metal precursor pulse may have a pulse duration of from 10 ms to 10 seconds, or about 1 second. The single layer of ligated metal bonded to the surface may have a thickness equivalent to a size of a single molecule of the metal ligand. For pulses of the metal precursor subsequent to the initial ALD metal fluoride layer, the metal precursor may react with the previously deposited ALD metal fluoride layer to bond a subsequent single layer of ligated metal to the outer surface of the ALD metal fluoride layer. After depositing and bonding the single layer of ligated metal to the outer surface of the mirror (e.g., etched surface 122 or outer surface of the previously deposited ALD metal fluoride layer), the ALD coating process may further include ceasing exposure of the mirror to the metal precursor. Ceasing exposure of the mirror to the metal precursor may include stopping the flow of the metal precursor into the ALD chamber. The ALD chamber may then be purged with an inert gas to remove any residual metal precursor from the ALD chamber before continuing with the ALD process.

After ceasing exposure of the optical component to the metal precursor and purging the ALD chamber, the ALD process part of the methods disclosed herein can include exposing the mirror having the layer of ligated metal bonded thereto to an oxygen source. The oxygen source can include water, water plasma, oxygen, oxygen plasma, ozone, ozone plasma, hydrogen peroxide, hydrogen peroxide plasma, oxygen-containing liquid, oxygen-containing gas, or combinations of these. The oxygen source may be in a liquid state, gaseous state, or plasma state. Exposing the ligated metal layer on the surface of the mirror to the oxygen source may comprise introducing a pulse containing the oxygen source into the ALD chamber containing the mirror. In embodiments, the oxygen source pulse may include the oxygen source or the oxygen source in combination with one or more inert gases, which may be any of the inert gases previously described herein. Exposing the mirror to the oxygen-containing pulse may cause oxidation of the ligated metal to form the metal oxide on the surfaces of the mirror. The oxygen source pulse may have a pulse duration sufficient to cause the oxygen source to react with at least 90%, at least 95%, at least 98%, at least 99%, or even at least 99.9% of the ligated metal bonded to the surfaces of the mirror. The oxygen source pulse may have a pulse duration of from 0.1 seconds to 1 second, or about 0.3 seconds. The ALD process may further include ceasing exposure of the mirror to the oxygen source pulse, such as by stopping the flow of the oxygen source into the ALD chamber at the end of the oxygen source pulse. In embodiments, the ALD chamber may then be purged with an inert gas after the oxygen source pulse, which may remove any residual oxygen and organic compounds from the ALD chamber.

The ALD process may further include, after the oxygen source pulse, exposing the mirror having the layer of metal oxide deposited on surfaces thereof to the fluorine source. Exposing the mirror to the fluorine source may comprise introducing a pulse containing the fluorine source to the ALD chamber containing the mirror. The fluorine source may be any of the compositions previously described herein for the fluorine source. In embodiments, the fluorine source is an SF₆-based fluorine source, such as but not limited to SF₆, SF₆ plasma, SF₆/Ar plasma, or combinations of these. The fluorine from the fluorine source may reduce the metal oxides to form the metal fluoride of the ALD protective layer 120 on the surfaces of the mirror to produce the enhanced aluminium mirror 100. The fluorine source pulse may have a duration sufficient to cause the fluorine to react with at least 90%, at least 95%, at least 98%, at least 99%, or even at least 99.9% of the metal oxide at the surfaces of the mirror to produce the enhanced aluminium mirror 100. The fluorine source pulse may have a pulse duration of from 10 ms to 30 s, such as from 10 ms to 20 s, from 10 ms to 10 s, from 1 s to 30 s, from 1 s to 20 s, from 1 s to 10 s, from 3 s to 30 s, from 3 s to 20 s, or from 3 s to 10 s. The process may further include ceasing exposure of the enhanced aluminium mirror 100 to the fluorine source, such as by stopping the flow of the fluorine source into the ALD chamber at the end of the fluorine source pulse. As previously discussed, exposing the optical component to the oxygen source after exposure to the metal precursor and before exposure to the fluorine source may reduce the concentration of carbon in the ALD protective layer 120 applied to the reflective coating 110 of the enhanced aluminium mirror 100 compared to alternating pulses of the metal precursor and the fluorine source without the pulse containing the oxygen source.

The mirror comprising the substrate 102 and the reflective coating 110 may be contacted with or exposed to the metal precursor and fluorine source or metal precursor, oxygen source, and fluorine source at operating conditions sufficient to cause the metal precursor, fluorine source, oxygen source, or combinations of these to undergo chemical reactions at the surfaces of the mirror to deposit the ALD protective layer 120 on top of the reflective coating 110. The ALD process may be conducted at a process temperature sufficient to cause the metal precursor, oxygen source, fluorine source, or combinations of these to undergo reactions at the surface of the optical component. In embodiments, the ALD process may include depositing the ALD coating on the surfaces of the optical component at a process temperature of from 120° C. to 250° C.

In embodiments, the ALD process can be a plasma-assisted ALD process, in which plasma materials are utilized for one or more of the metal precursor pulse, oxygen source pulse, fluorine source pulse, or combinations of these. The metal precursor, oxygen source, fluorine source, or combinations of these may be converted into a plasma by heating the materials and subjecting the materials to an electric current or a strong electromagnetic field. The materials (e.g., metal precursor, oxygen source, fluorine source, or combinations of these) may be heated to the ALD process temperature and subjected to an electric current sufficient to convert the materials into a plasma. In embodiments, converting the materials (e.g., metal precursor, oxygen source, fluorine source, or combinations thereof) into a plasma may comprise heating the materials to a temperature of from 100° C. to 325° C., or from 120° C. to 250° C., and applying an electric current having a power of from 100 Watts (W) to 300 W, or about 200 W.

The ALD process may be repeated a plurality of times to build up the thickness of the ALD protective layer 120. Each iteration of the ALD process may add another molecular layer of the ALD metal fluoride to the ALD protective layer 120. The thickness of the ALD protective layer 120 can be controlled by controlling the number of iterations of the ALD process, thus, controlling the number of molecular layers of ALD metal fluoride are present in the ALD protective layer 120. The growth rate of the ALD process for producing the ALD protective layer 120 can be about 0.5 Angstroms per cycle, where a cycle comprises one sequence of metal precursor followed by fluorine source, or one complete sequence of metal precursor-oxygen source-fluorine source.

In embodiments, the ALD protective layer 120 may comprise a stack of different ALD metal fluoride layers, wherein each of the different ALD metal fluoride layers comprises a metal fluoride having a different metal from the metal fluorides in adjacent layers in the stack. In embodiments, the ALD protective layer 120 may comprise a stack of metal fluorides comprising an amorphous ALD-AlF₃ layer disposed between layers of polycrystalline ALD metal fluoride layers, such as but not limited to ALD-CaF₂, ALD-MgF₂, or ALD-LiF 2 layers. Other combinations of different metal fluoride layers formed into a stack are also contemplated.

Referring again to FIG. 2, the enhanced aluminium mirrors 100 of the present disclosure include the substrate 102, the reflective coating 110 comprising PVD-Al deposited on the mirror surface of the substrate 102, and one or more ALD protective layers 120 deposited over top of the reflective coating 110. The ALD protective layer 120 may be bonded to the etched surface 122 of the reflective coating 110. In embodiments, the ALD protective layers 120 can also be bonded to other surfaces of the substrate 102 that do not have the reflective coating 110, in which case the ALD protective layer 120 can be bonded directly to surface of the substrate 102. The ALD protective layer 120 can include a metal fluoride, such as but not limited to AlF₃, MgF₂, CaF₂, LiF, or combinations thereof. In embodiments, the ALD protective layer 120 may comprise an ALD metal fluoride layer that includes greater than or equal to 90%, greater than or equal to 95%, greater than or equal to 98%, greater than or equal to 99%, or greater than or equal to 99.9% by weight metal fluoride based on the total weight of the ALD protective layer 120.

In embodiments, the ALD protective layer 120 may be an ALD metal fluoride and may include sulfur in addition to the metal fluoride. In embodiments, the ALD protective layer may comprise an ALD metal fluoride layer and may have a sulfur content in the ALD metal fluoride layer of greater than zero parts per million (ppm), such as from greater than zero ppm to 300 ppm, or from greater than 1 ppm to 250 ppm, or from greater than 5 ppm to 200 ppm, or from greater than 10 ppm to 150 ppm, or from greater than 25 ppm to 125 ppm.

In embodiments, the ALD protective layer 120 may comprise the ALD metal fluoride and may be substantially free of carbon. In embodiments, the ALD protective layer 120 may have a concentration of carbon of less than or equal to 10,000 ppm, or less than or equal to 5,000 ppm, or less than or equal to 1,000 ppm, or less than 500 ppm in the ALD protective layer 120. In embodiments, the reflective coating 110, the ALD protective layer 120, or both have less than 5 atomic percent (at %) oxygen, such as less than or equal to 4 at %, less than or equal to 3 at %, less than or equal to 2 at %, or even less than or equal to 1 at % oxygen, where atomic percent of oxygen is the number of oxygen atoms in a structure divided by the total number of atoms in the structure. In embodiments, the reflective coating 110, the ALD protective layer 120, or both can have from at % to about 5 at % oxygen atoms.

Referring to FIG. 2, the ALD protective layer 120 can have a total thickness t_{ALD} that is sufficient to cover the etched surface 122 of the reflective coating 110 without substantial exposure of the aluminium of the reflective layer 110 to the atmosphere within the coated area. In embodiments, the ALD protective layer have a total thickness t_{ALD} of less than or equal to 40 nm, less than or equal to 30, less than or equal to 25 nm, less than or equal to 20 nm, or even less than or equal to 10 nm. In embodiments, the ALD protective layer 120 can have a total thickness t_{ALD} of greater than or equal to 1 nm, greater than or equal to 3 nm, greater than or equal to 5 nm, or even greater than or equal to 10 nm. In embodiments, the ALD protective layer 120 can have a total thickness t_{ALD} of from 1 nm to 40 nm, from 1 nm to 30 nm, from 1 nm to 25 nm, from 1 nm to 20 nm, from 1 nm to 10 nm, from 3 nm to 40 nm, from 3 nm to 30 nm, from 3 nm to 25 nm, from 3 nm to 20 nm, from 3 nm to 10 nm, from 5 nm to 40 nm, from 5 nm to 30 nm, from 5 nm to 25 nm, from 5 nm to 20 nm, from 5 nm to 10 nm, from 10 nm to 40 nm, from 10 nm to 30 nm, from 10 nm to 25 nm, from 10 nm to 20 nm, from 20 nm to 40 nm, or from 20 nm to 30 nm. In embodiments, the ALD protective layer can include multiple ALD metal fluoride layers, where each of the multiple ALD metal fluoride layers comprises a different coating material. In these embodiments, each of the multiple ALD metal fluoride layers can have a thickness of from 1 nm to 30 nm, from 1 nm to 25 nm, from 1 nm to 20 nm, from 1 nm to 10 nm, from 3 nm to 30 nm, from 3 nm to 25 nm, from 3 nm to 20 nm, from 3 nm to 10 nm, from 5 nm to 30 nm, from 5 nm to 25 nm, from 5 nm to 20 nm, from 5 nm to 10 nm, from 10 nm to 30 nm, from 10 nm to 25 nm, from 10 nm to 20 nm, or from 10 nm to 30 nm. The total thickness t_{ALD} of the ALD protective layer 120 may be the sum of the thicknesses of each of the individual ALD metal fluoride layers for an ALD protective layer 120 comprising a plurality of different ALD metal fluorides.

The ALD protective layer 120 may be a conformal coating having a uniform thickness across all coated surfaces. In embodiments, the ALD protective layer 120 may have a thickness that varies by less than or equal to 5%, less than or equal to 4%, less than or equal to 3%, less than or equal to 2%, less than or equal to 1%, or even less than or equal to 0.5% from an average thickness of the ALD protective layer 120. The average thickness of the ALD protective layer 120 is the total thickness t_{ALD} of the ALD protective layer 120 averaged over all of the surface area of the surfaces in contact with the ALD protective layer 120.

The enhanced aluminium mirror 100 may have a reflectance of light in the wavelength range of from 110 nm to 180 nm (or from 150 nm to 180 nm) that is greater than or equal to 77%, greater than or equal to 80%, greater than or equal to 81%, or even greater than or equal to 82%. The reflectance was measured by using a commercial VUV spectrophotometer. In embodiments, the enhanced aluminium mirror 100 can include a high reflective index ALD layer, such as but not limited to a lanthanum fluoride ALD layer, a gadolinium fluoride ALD layer, or other high reflective index layer. When the ALD protective layer 120 includes a high reflective index ALD layer, the enhanced aluminium mirror 100 can have a reflectance of VUV wavelength light greater than the reflectance of the substrate with the pure aluminium reflective coating, such as a reflectance greater than 90%, or even greater than 92%.

Referring to FIG. 2, the ALD coating process may result in deposition of the ALD protective layer evenly over one, a plurality, or all of the surfaces of the substrate, not just the mirror surface 104 having the reflective coating 110. In embodiments, the enhanced aluminium mirror 100 can include the ALD protective layer 120 deposited on and/or contacting at least 95%, at least 98%, at least 99%, or even at least 99.5% of the surfaces of the enhanced aluminium mirror intended to be coated (e.g., the etched surface 122 of the reflective coating 110 and other surfaces of the substrate 102). Surfaces of the enhanced aluminium mirror 100 that are intended to be coated are surfaces that are not intentionally masked to prevent ALD coating. The ALD protective layer 120 may also be deposited on and/or may be in contact with other reflective surfaces of the optical components, such as surfaces on which the laser beam or light beam is not expected to be incident.

Referring now to FIG. 11, as previously discussed, the enhanced aluminium mirror 100 can have an ALD protective layer 120 that comprises a plurality of ALD protective layers, such as but not limited to a first ALD protective layer 140, a second ALD protective layer 150, etc., which are applied to the surfaces of the enhanced aluminium mirror 100. In embodiments, the enhanced aluminium mirror 100 may have the first ALD protective layer 140 directly bonded to and directly contacting the etched surface 122 of the reflective layer 110, and at least one second ALD protective layer 150 applied on top of the first ALD protective layer 140. The second ALD protective layer 150 may be a material different from the first ALD protective layer 140. The second ALD protective layer 150 can be directly coupled to the first ALD protective layer 140 such that an inner surface of the second ALD protective layer 150 contacts and is bonded to an outer surface of the first ALD protective layer 140 without any intervening layer or coating disposed between the first ALD protective layer 140 and the second ALD protective layer 150. One or more additional ALD protective layers may be deposited on top of the second ALD protective layer 150 to provide a stack of ALD coating layers. The first ALD protective layer 140, the second ALD protective layers 150, subsequent ALD coating layers, or combinations of these, may each have a thickness of up to 40 nm, such as from 1 nm to 40 nm, or from 5 nm to 30 nm. In embodiments, one or more of the ALD protective layers may have a thickness greater than 40 nm. In embodiments, the thickness t_{ALD1} of the first ALD protective layer 140, the thickness t_{ALD2} of the second ALD protective layer 150, or both can be from 1 nm to 40 nm, from 3 nm to 30 nm, or from 5 nm to 20 nm.

The enhanced aluminium mirror 100 comprising a plurality of ALD protective layers 120 can be prepared by depositing the aluminium reflective layer 110 to the mirror surface 104 of the substrate using a PVD process, etching the outer surface 112 of the reflective layer 110 by the ALE process to produce the etched surface 122 of the reflective layer 110, depositing the first ALD protective layer 140 to the etched surface 122 of the reflective layer 110, and then depositing the second ALD protective layer 150 onto the outer surface of the first ALD protective layer 140. The first ALD protective layer 140 is then disposed between the reflective layer 110 and the second ALD protective layer 150. After depositing the second ALD protective layer 150, subsequent ALD protective layers can be applied until the desired ALD coating structure is attained. The first ALD protective layer 140, the second ALD protective layer 150, and any other subsequent ALD protective layers may be deposited onto one or more surfaces of the enhanced aluminium mirror 100 according any of the ALD processes previously discussed herein.

In embodiments, the enhanced aluminium mirror 100 can include the substrate 102, the reflective layer 110 comprising PVD-Al, a first ALD protective layer 140 comprising ALD-AlF₃ deposed on an etched surface 122 of the reflective layer 110, and a second ALD protective layer 150 comprising ALD-MgF₂ deposited on the outer surface of the first ALD protective layer. In embodiments, the first ALD protective layer 140 comprising the ALD-AlF₃ can have a thickness of from 5 to 25, and the second ALD protective layer 150 comprising ALD-MgF₂ can have a thickness of from 5 nm to 25 nm. In embodiments, the enhanced aluminium mirror 100 can comprise the first ALD protective layer 140 comprising the ALD-AlF₃ having a thickness of 5 nm and the second ALD protective layer 150 comprising ALD-MgF₂ having a thickness of 23 nm.

In embodiments, the enhanced aluminium mirror 100 can comprise the ALD protective layer 120 that includes a plurality of alternating ALD-AlF₃ and ALD-MgF₂ layers. In embodiments, the enhanced aluminium mirror can include a first ALD protective layer comprising nm of ALD-AlF₃, a second ALD protective layer comprising 9 nm of ALD-MgF₂, a third ALD protective layer comprising 5 nm of ALD-AlF₃, and a fourth ALD protective layer comprising 9 nm of ALD-MgF₂. In embodiments, the enhanced aluminium mirror 100 can include a first ALD protective layer comprising 5 nm of ALD-AlF₃, a second ALD protective layer comprising 2 nm of ALD-MgF₂, a third ALD protective layer comprising 5 nm of ALD-AlF₃, a fourth ALD protective layer comprising 2 nm of ALD-MgF₂, a fifth ALD protective layer comprising 5 nm of ALD-AlF₃, and a sixth ALD protective layer comprising 2 nm of ALD-MgF₂. Other combinations of ALD materials, numbers of ALD protective layers, and layer thickness are contemplated.

In embodiments, the enhanced aluminium mirror 100 can include the substrate 102, the reflective coating 110, the first ALD protective layer 140, and the second ALD protective layer 150, where the second ALD protective layer 150 comprises a high reflective index metal fluoride that can improve the reflectance of the enhanced aluminium mirror 100 compared to aluminium mirrors without the high reflective index metal fluoride. In embodiments, the ALD protective layer 120 of the enhanced aluminium mirror 100 can include the first ALD protective layer comprising ALD-AlF₃ and the second ALD protective layer 150 comprising lanthanum fluoride (LaF₃), gadolinium fluoride (GdF₃), or other high reflective index metal fluoride. In embodiments, the enhanced aluminium mirror 100 can include the aluminium reflective layer 110 having a thickness of from 70 nm to 100 nm, the first ALD protective layer 140 comprising from 10 nm to 30 nm ALD-AlF₃, and the second ALD protective layer 150 comprising from 5 nm to 20 nm ALD-LaF₃.

The enhanced aluminium mirrors 100 of the present disclosure having the reflective coating 110 comprising PVD-Al and the ALD protective layer 120 comprising ALD metal fluoride coatings can be used as mirrors in various VUV or EUV applications, such as VUV or EUV lithography or inspection systems for making and/or inspecting microelectronics. The enhanced aluminium mirrors 100 can be used with lasers having wavelength in the VUV range such as but not limited to beams having wavelengths of from 110 nm to 180 nm. In embodiments, the enhanced aluminium mirrors 100 can be used with beams having wavelengths of greater than 180 nm.

### EXAMPLES

The embodiments of coated optical components and ALD process for producing the coated optical components described herein will be further clarified by the following examples.

### Example 1—ALD Protective Layer Comprising AlF₃—4 nm

In Example 1, an enhanced aluminium mirror was prepared according to the methods disclosed herein and represented in the flow chart in FIG. 9. For the enhanced aluminium mirror of Example 1, the substrate was first coated with an aluminium reflective layer in a PVD process. The reflective layer had an initial thickness of 100 nm. The substrate having the reflective layer was then transferred to the ALD chamber of an ALD system. The substrate and reflective layer were subjected to ALE in the ALD chamber to remove 4 nm of the reflective layer. The ALE process included subjecting the substrate and reflective layer to alternating pulses of a fluorine source and the organometallic compound. For Example 1, the fluorine source was an SF₆/Ar plasma and the organometallic compound was trimethylaluminium (TMA). The ALE was conducted at 225° C. For each fluorine source pulse, the substrate and reflective coating were exposed to the SF6/Ar plasma for an exposure time of 7 seconds at 300 W ICP power. The ALD chamber was purged with Ar after the fluorine pulse. For each organometallic pulse, the duration of exposure to the TMA was 400 ms, followed by closing of the throttle valve of the ALD chamber for a shut in period of 10 seconds. Following shut in, the throttle valve was opened, and the ALD chamber was purged again with Ar. The ALE process was repeated until 4 nm of the reflective coating was removed. The etch rate was 1.1 Angstroms per cycle for the ALE process.

Following ALE, the etched surface of the reflective layer was coated with an ALD protective layer comprising 4 nm of AlF₃. The ALD process was conducted by exposing the etched surface of the protective layer to alternating pulses of the metal precursor (TMA) and fluorine source, starting with the pulse of the TMA. The ALD process was conducted at a temperature of 225° C. For the TMA pulse, the exposure time was 40 ms and the throttle valve was maintained in the open position during the TMA pulse. The fluorine pulse was conducted with an exposure time and power that were the same as for the ALE process. The growth rate of the ALD protective layer was 0.5 Angstroms per cycle. The resulting enhanced aluminium mirror included the substrate, the aluminium metal reflective layer having a thickness of 96 nm, and the ALD protective layer comprising AlF₃ having a thickness of 4 nm.

### Comparative Example 2—PVD Only

For Comparative Example 2, an aluminium mirror was prepared by depositing the aluminium reflective coating through a PVD process and then passivating the reflective coating by depositing a low-density PVD-AlF₃ layer and a dense PVD-AlF₃ layer according to the method represented in the flow chart of FIG. 5. The aluminium mirror of Comparative Example 2 included a 100 nm PVD-Al reflective coating, a 15 nm low-density PVD-AlF₃ layer, and a 10 nm dense PVD-AlF₃ layer. The reflective coating comprising the PVD-Al was applied at room temperature through a PVD process. Following deposition of the aluminium reflective coating, the PVD process was used to form the low-density PVD-AlF₃ layer at room temperature. Following deposition of the low-density PVD-AlF₃ layer, the aluminium mirror was heated to a temperature of 200° C. and the dense PVD-AlF₃ layer was applied. The total thickness of the PVD passivation layers was 25 nm.

### Comparative Example 3—Hybrid

For Comparative Example 3, an aluminium mirror was prepared according to the hybrid method represented in the flow chart of FIG. 6 by depositing the aluminium reflective coating through a PVD process and then passivating the reflective coating by depositing a low-density PVD-AlF₃ layer and depositing a ALD-AlF₃ protective layer deposited by an ALD process. The aluminium mirror of Comparative Example 3 included a 100 nm PVD-Al reflective coating, a 15 nm low-density PVD-AlF₃ layer, and a 10 nm dense ALD-AlF₃ layer. The reflective coating comprising the PVD-Al was applied at room temperature through a PVD process. Following deposition of the aluminium reflective coating, the PVD process was used to form the low-density PVD-AlF₃ layer at room temperature. Following deposition of the PVD-AlF₃ layer, the mirror was transferred from the PVD system to the ALD chamber of the ALD system. In the ALD chamber, the aluminium mirror comprising the reflective coating and low-density PVD-AlF₃ layer was subjected to fluorine cleaning to remove as much carbon and oxygen impurities as possible. The fluorine cleaning treatment included exposing the reflective coating and low-density PVD-AlF₃ layer to sulfur hexafluoride (SF₆) plasma at 150° C. for a period of 30 seconds in the ALD chamber. Following the fluorine cleaning treatment, the ALD protective layer comprising ALD-AlF₃ was deposited onto the outer surface of the low-density PVD-AlF₃ layer. For the ALD process, the metal precursor for the metal precursor pulse was TMA, and the fluorine source was SF₆/Ar plasma. The ALD process for Comparative Example 3 was conducted at a temperature of 150° C. The sequence, pulse duration, and power were the same as previously described for the ALD process in Example 1.

### Example 4—Reflectance

In Example 4, the reflectance of the enhanced aluminium mirror of Example 1 and the aluminium mirrors of Comparative Examples 2 and 3 were evaluated according to the methods disclosed herein. In Example 4, the reflectance was measured by using a commercial VUV spectrophotometer. Referring again to FIG. 8A, the reflectance (y-axis) as a function of wavelength (x-axis) is graphically depicted for the enhanced aluminium mirror of Example 1 (806), the aluminium mirror of Comparative Example 2 (802), and the aluminium mirror of Comparative Example 3 (804). As shown in FIG. 8A, the PVD-only aluminium mirror of Comparative Example 2 (802) showed a significant reduction in reflectance down to 0.70 at wavelengths between 150 and 180, indicating the presence of aluminium oxides in the various coating layers. The aluminium mirror of Comparative Example 3 (804), which comprised the PVD-Al layer, low-density PVD-AlF₃ layer, and the ALD-AlF₃ protective layer, also exhibited a substantial decrease in reflectance of down to about 0.75 between 150 nm and 180 nm wavelengths. Though providing better reflectance performance compared to the PVD-only aluminium mirror of Comparative Example 2 (802), the aluminium mirror of Comparative Example 3 (804) still exhibited degradation of the reflectance performance over the VUV wavelength range due to oxidation of aluminium and accumulation of aluminium oxides in the reflective coatings and protective layers.

As shown in FIG. 8A, the enhanced aluminium mirror of Example 1 (806) exhibited greater reflection over the wavelength range of 150 nm to 180 nm compared to the mirrors of Comparative Example 2 (802) and Comparative Example 3 (803). It is further noted that the protective coating for the enhanced aluminium mirror of Example 1 had an ALD protective layer of only 4 nm, while the mirrors of Comparative Examples 2 and 3 had a total thickness of the passivation layers (PVD-AlF₃, ALD-AlF₃, or both) of 25 nm. Thus, the enhanced aluminium mirror of Example 1 (806) provided superior reflection performance and protection of the aluminium of the reflective coating while enabling a much thinner thickness of the ALD protective layer compared to the PVD-only mirror of Comparative Example 2 and the mirror made by the hybrid PVD-ALD process in Comparative Example 3.

### Example 5—Enhanced Aluminium Mirror with Two ALD Protective Layers

For Example 5, an enhanced aluminium mirror was prepared having a first ALD protective layer comprising ALD-AlF₃ and a second ALD protective layer comprising ALD-MgF₂. The aluminium reflective coating having a thickness of 100 nm was deposited using the PVD process. Following PVD, mirror was transferred to the ALD chamber of the ALD process and the ALE process was conducted to remove 4 nm of the reflective coating. The ALE process steps, materials, and conditions were the same as those previously described in Example 1. The final thickness of the reflective coating after etching was 96 nm. The first ALD protective layer comprising ALD-AlF₃ was deposited according to the process described in Example 1. The thickness of the first ALD protective layer was 12 nm.

The second ALD protective layer was then deposited onto the first ALD protective layer. For the second ALD protective layer, the ALD chamber was cooled down to a temperature of 150° C. The magnesium precursor was (EtCp)₂Mg (i.e., bis(ethylcyclopentadienyl) magnesium). The bubbler temperature was set to 92° C. and the ICP plasma power was 200 W. The metal precursor pulse comprising the (EtCp)₂Mg had a pulse duration of 1 second followed by a purge with inert gas for 9 seconds. Following the metal precursor pulse and purge, a water pulse having a duration of 40 milliseconds was conducted followed by purging for 8 seconds with inert gas. After the water pulse and purge, the optical component was subjected to a fluorine source pulse comprising a mixture of SF₆ and Argon. The SF₆/Argon flow ratio was 30/15, and the fluorine source pulse had a duration of 7 seconds. The fluorine source pulse was followed by a purge pulse. The sequence of metal precursor pulse/water pulse/fluorine source pulse was repeated until the thickness of the MgF₂ ALD coating attained a thickness of 9 nm.

### Example 6—SIMS

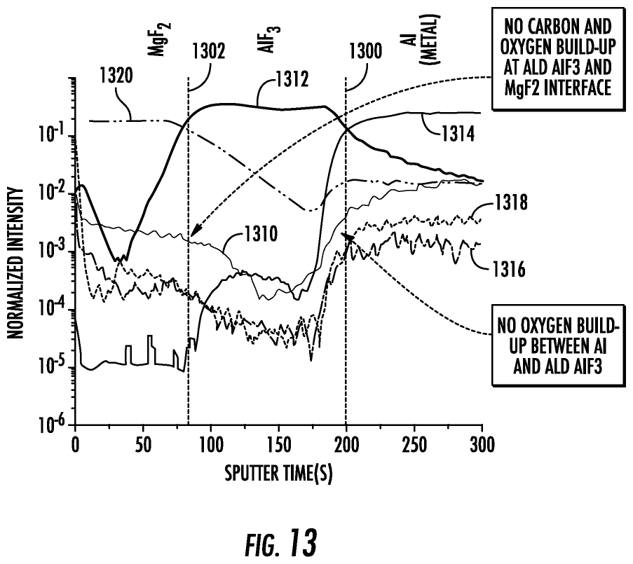

For Example 6, the enhanced aluminium mirrors of Examples 1 and 5 and the aluminium mirrors of Comparative Examples 2 and 3 were analyzed using secondary ion mass spectrometry (SIMS) to evaluate the relative amounts of aluminium, aluminium fluoride, oxygen, carbon, hydrogen in the various coating layers. The secondary ion mass spectrometry analysis was performed using a secondary ion mass spectrometer. The SIMS analysis was conducted by sputtering the surface of the mirror with cesium ions (Cs⁺) having a kinetic energy of 2 kV and conducting analysis in positive mode with 30 kV Bi₃⁺ ions. In FIGS. 12-15, the broken vertical lines represent the interface between the various coatings and layers, and each layer is indicated in the space above the graph.

Referring now to FIG. 12, the SIMS analysis for the enhanced aluminium mirror of Example 1 is graphically depicted. Reference number 1200 indicates the transition point between the PVD-Al of the reflective coating and the ALD-AlF₃ of the ALD protective layer. In FIG. 12 the normalized amount of each species in coating (y-axis) is plotted as a function of depth from the outer surface of the ALD protective layer (y-axis). The following Table 2 provides a cross reference between the reference numbers in FIG. 12 and the corresponding species.

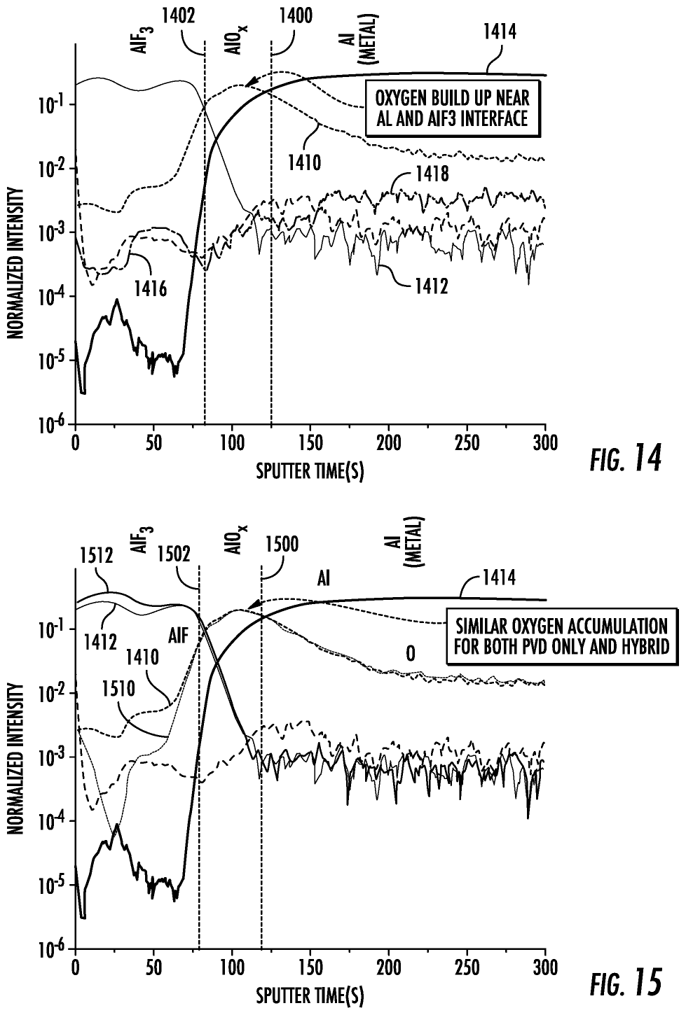

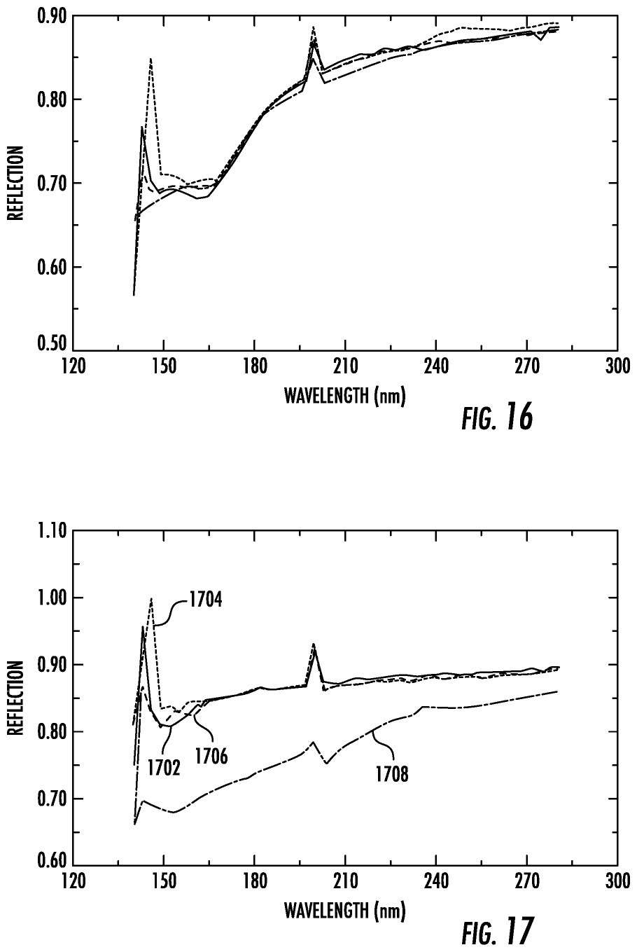

TABLE 2

| | Reference | Reference | Reference | Reference |
|---|---|---|---|---|
| | Number | Number | Number | Number |
| Species | FIG. 12 | FIG. 13 | FIG. 14 | FIG. 15 |
| Oxygen | 1210 | 1310 | 1410 | 1510 |
| Aluminium | 1212 | 1312 | 1412 | 1512 |
| Fluoride | | | | |
| Aluminium metal | 1214 | 1314 | 1414 | — |
| Carbon | 1216 | 1316 | 1416 | — |
| Hydrogen | 1218 | 1318 | 1418 | — |
| Magnesium | — | 1320 | — | — |
| Fluoride | | | | |

As shown in FIG. 12, the normalized amount of oxygen in the coatings does not increase at the interface 1200 between the aluminium reflective layer and the ALD protective layer comprising the ALD-AlF₃. This indicates that the ALE process effectively removed all of the native oxide formed on the surface of the aluminium reflective coating. Additionally, no subsequent build-up of interfacial oxides between the reflective layer 110 and the ALD protective layer 120 in the enhanced aluminium mirror of Example 1 was observed.

Referring now to FIG. 13, the SIMS analysis for the enhanced aluminium mirror of Example 5 is graphically depicted. Reference number 1300 indicates the transition point between the PVD-Al of the reflective coating and the ALD-AlF₃ of the first ALD protective layer, and reference number 1302 indicates the transition point between the ALD-AlF₃ of the first protective layer and the ALD-MgF₂ of the second ALD protective layer. In FIG. 13, the normalized amount of each species in coating (y-axis) is plotted as a function of depth from the outer surface of the second ALD protective layer (y-axis). Table 2 provides a cross reference between the reference numbers in FIG. 13 and the corresponding species. As shown in FIG. 13, the normalized amount of oxygen in the coatings does not increase at the interface 1200 between the aluminium reflective layer and the ALD protective layer comprising the ALD-AlF₃, and in fact decreases in the ALD-AlF₃ layer. This indicates that the ALE process effectively removed all of the native oxide formed on the surface of the aluminium reflective coating. Additionally, no subsequent build-up of interfacial oxides between the reflective layer and the first ALD protective layer in the enhanced aluminium mirror of Example 5 was observed. Further, no carbon or oxygen accumulation was observed near the interface 1302 between the first ALD coating and the second ALD coating, which indicates that no oxidation occurred during cooling down of the ALD chamber in the transition from ALD-AlF₃ to ALD-MgF₂.

Referring now to FIG. 14, the SIMS analysis for the PVD-only aluminium mirror of Comparative Example 2 is graphically depicted. Reference number 1400 indicates the transition point between the PVD-Al of the reflective coating and a layer of aluminium oxide (AlOₓ)formed on the outer surface of the reflective layer, and reference number 1402 indicates the transition point between the layer of aluminium oxides and the passivation layer comprising the PVD-AlF₃. In FIG. 14, the normalized amount of each species in coating (y-axis) is plotted as a function of depth from the outer surface of the PVD-AlF₃ layer (y-axis). Table 2 provides a cross reference between the reference numbers in FIG. 14 and the corresponding species. As shown in FIG. 14, the normalized oxygen content increases in the region of the interface 1400 and then decreases again at the interface 1402. This localized increase in aluminium oxide bonds indicates the build-up of oxygen species on the surface of the PVD-Al reflective layer, thus indicating reaction of residual oxygen in the PVD chamber with the aluminium during deposition of the PVD-AlF₃ passivation layer.

Referring now to FIG. 15, the SIMS analysis for the aluminium mirror of Comparative Example 3 is added to the SIMS analysis for the PVD-only aluminium mirror of Comparative Example 2. Reference number 1500 indicates the transition point between the PVD-Al of the reflective coating and a layer of aluminium oxide (AlOₓ) formed on the outer surface of the reflective layer, and reference number 1502 indicates the transition point between the layer of aluminium oxides and the hybrid passivation layer comprising the PVD-AlF₃ and ALD-AlF₃. In FIG. 15, the normalized amount of each of oxygen, aluminium, and AlF₃ in the coating (y-axis) is plotted as a function of depth from the outer surface of the ALD-AlF₃ layer (y-axis). Table 2 provides a cross reference between the reference numbers in FIG. 15 and the corresponding species. As shown in FIG. 15, the aluminium mirror of Comparative Example 3 exhibits the increase in oxides at the transition between the PVD-Al of the reflective layer and the AlF₃ of the protective layers. This is similar to the increase in oxides observed for the PVD-only aluminium mirror of Comparative Example 2. Without intended to be bound by any particular theory, it is believed that the oxidation of the aluminium surface of the reflective layer in Comparative Example 3 happens mainly during the room temperature deposition of the low-density PVD-AlF₃ layer. Compared to PVD-AlF₃, ALD-AlF₃ has lower oxygen content, because ALD condition has more reducing environment than that of PVD.

### Example 7—UV Exposure

In Example 7, the enhanced aluminium mirror of Example 1 and a PVD-only aluminium mirror comprising a PVD-AlF₃ passivation layer were subjected to UV ozone to evaluate the effectiveness of the protective layers for reducing or preventing oxidation of the reflective layer. As previously indicated, the enhanced aluminium mirror of Example 1 had an ALD protective layer comprising ALD-AlF₃ and having a thickness of 4 nm. The PVD-only aluminium mirror had a protective layer comprising PVD-AlF₃ and having a thickness of 18 nm. The exposure time was increased from 0 to 99 minutes to 2×99 minutes to 3×99 minutes.

Referring now to FIG. 16, the reflection of the PVD-only aluminium mirror (Y-axis) as a function of wavelength (x-axis) shows a decrease in reflection for wavelengths in the range of 150-180, which indicates the occurrence of oxidation even without exposure to the UV ozone. Referring now to FIG. 17, the reflectance (y-axis) as a function of wavelength (x-axis) for the enhanced aluminium mirror of Example 1 is graphically depicted. The following Table 3 provide cross-reference between the reference numbers in FIG. 17 and the exposure time of the mirror to the UV ozone.

TABLE 1

| Reference Number in FIG. 17 | Exposure Time to UV Ozone |
|---|---|
| 1702 | 0 |
| 1704 | 1 × 99 minutes |
| 1706 | 2 × 99 minutes |
| 1708 | 3 × 99 minutes |

As shown in FIG. 17, for each of reference numbers 1702, 1704, 1706, the refection was greater than 0.8 over the wavelength range of from 150-180 nm. When the exposure to the UV Ozone was 3×99 minutes, the enhanced aluminium mirror exhibited a decrease in the reflectance indicative of oxidation. However, FIG. 17 demonstrates that even an ALD-ALF 3 protective layer having a thickness of down to about 4 nm can provide good protection to the PVD-Al mirror.

### Example 8—Enhanced Aluminium Mirror with High Reflective Index Layer

In Example 8, a prophetic example of an enhanced aluminium mirror can include a first ALD protective layer and a second ALD protective layer comprising a high reflective index fluoride. For Example 8, the high reflective index fluoride is lanthanum fluoride (LaF₃). The aluminium reflective coating is a PVD aluminium coating and has a thickness of 100 nm. The first ALD protective layer comprises ALD-AlF₃ and has a thickness of 28 nm. The second ALD protective layer comprises the ALD-LaF₃. The ALD-LaF₃ of the second ALD protective layer can be prepared by subjecting the mirror to an ALD process comprising alternating pulses of a lanthanum precursor and a fluorine source. The ALD process for depositing the ALD-LaF₃ can be conducted at a temperature in the range of from 250° C. to 350° C. The lanthanum precursor can be any of the lanthanum precursors disclosed herein, such as but not limited to tris(N,N′-diisopropylformamidinato) lanthanum, and each of the lanthanum precursor pulses can have a pulse duration of about 2 seconds. The fluorine pulses can be conducted as previously discussed herein. The thickness of the second ALD protective layer comprising the ALD-LaF₃ is 10 nm.

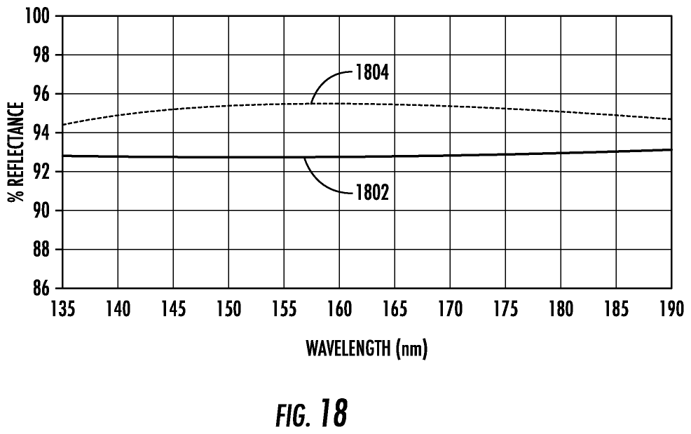

The theoretical reflectance of the enhanced aluminium mirror of Example 8 is calculated based on the properties of the materials in each layer of the reflective coating and ALD protective layers of the enhanced aluminium mirror of Example 8. For comparison, a theoretical reflectance of an aluminium mirror comprising only the reflective coating comprising the PVD-Al as a function of wavelength is also calculated. Referring now to FIG. 18, the reflectance (y-axis) as a function of wavelength (x-axis) for the enhanced aluminium mirror of Example 8 and the mirror comprising the aluminium reflective layer only are graphically depicted. In FIG. 18, the solid line (ref. no. 1802) is the reflectance of the aluminium only mirror and the broken line (ref. no. 1804) is the reflectance of the enhanced aluminium mirror of Example 8. As shown in FIG. 18, the presence of the high reflective index ALD-LaF₃ can improve the theoretical reflectance performance of the enhanced aluminium mirror compared to the mirror having only the PVD-Al reflective layer.

Humidity Test

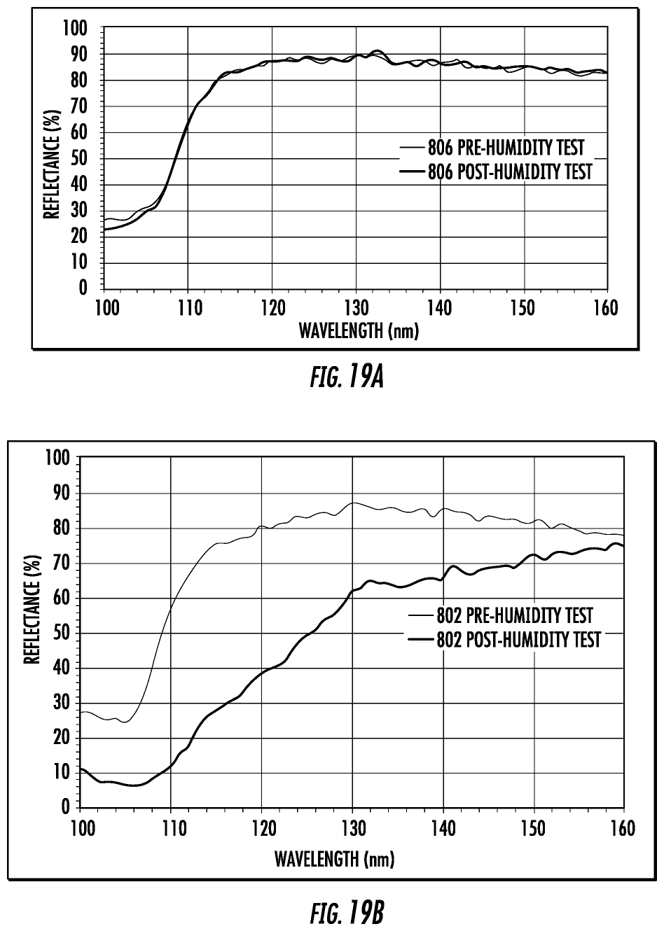

With reference again to FIG. 8A, the aluminium mirrors of reference 806 and 802 were each subjected to a humidity test to determine the stability of the respective coating on each mirror. FIG. 19A shows the results of the aluminium mirror of reference 806, and FIG. 19B shows the results of the aluminium mirror of reference 802. The humidity test included subjecting the aluminium mirrors to an 80% humid atmosphere at a temperature of 80° C. for a duration of 1 hour. The reflectance of each mirror was measured before and after the humidity test. As shown in FIG. 19A, the enhanced aluminium mirror of 806 has virtually the same reflectance after the humidity test as it had before, thus showing the durability and stability of the enhanced aluminium mirror 806. In contrast, as shown in FIG. 9B, the aluminium mirror 802 has a much lower reflectance after the humidity test than before the test.

It will be apparent to those skilled in the art that various modifications and variations can be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

What is claimed is:

1. A method of making an enhanced aluminium mirror for vacuum ultraviolet (VUV) optics, the method comprising:
depositing a reflective coating comprising aluminium metal to at least one surface of a substrate through physical vapor deposition (PVD) in a PVD system to produce a mirror comprising the substrate and the reflective coating;
removing aluminium oxides from an outer surface of the reflective coating by conducting atomic layer etching (ALE) in an atomic layer deposition (ALD) system to produce an etched surface of the reflective coating; and
depositing an ALD protective layer onto the etched surface of the reflective coating by conducting atomic layer deposition in the ALD system to produce the enhanced aluminium mirror comprising the substrate, the reflective coating deposited on the substrate, and the ALD protective layer covering the etched surface of the reflective coating.

2. The method of claim 1, further comprising transferring the substrate comprising the reflective coating from the PVD system to the ALD system, wherein transferring the substrate having the reflective coating to the ALD system exposes the reflective coating to oxygen resulting in oxidation of aluminium at an outer surface of the reflective coating to form aluminium oxides.

3. The method of claim 1, wherein the atomic layer etching in the ALD system comprises exposing the substrate and the reflective coating to alternating pulses of a fluorine source and an organometallic compound, wherein:
exposing the substrate and reflective coating to a pulse comprising the fluorine source converts the aluminium oxides to aluminium fluoride to form a thin layer of aluminium fluoride on the outer surface of the reflective coating; and
exposing the thin layer of aluminium fluoride to a pulse comprising the organometallic compound causes the aluminium fluoride to react to form a volatile organometallic compound that is released from the outer surface of the reflective coating.

4. The method of claim 3, further comprising exposing the reflective coating to alternating pulses of the fluorine source and the organometallic compound at a temperature of from 150° C. to 325° C. and an ICP power of from 50 Watts (W) to 600 W.

5. The method of claim 3, further comprising exposing the etched surface of the reflective coating to the fluorine source for an exposure time of from 1 second to 60 seconds.

6. The method of claim 3, wherein the fluorine source comprises SF₆, SF₆ plasma, or a plasma comprising SF₆ and argon (Ar), and the organometallic compound comprises trimethylaluminium (TMA), triethylaluminium (TEA), dimethylaluminium chloride (DMAC), silicon tetrachloride (SiCl₄), aluminium hexafluoroacetylacetonate (Al(hfac)₃), tri-i-butylaluminium (Al(iBu)₃), tin(II) acetylacetonate (Sn(acac)₂), tris(2,2,6,6-tetramethyl-3,5-heptanedionato)aluminium (i.e., Al(TMHD)₃, or combinations of these.

7. The method of claim 3, further comprising exposing the thin layer of aluminium fluoride to the organometallic compound for a total exposure time of from 10 milliseconds (ms) to 60,000 ms, where the total exposure time is equal to a pulse length of the pulse of the organometallic compound and a shut-in period.

8. The method of claim 3, further comprising exposing the thin layer of aluminium fluoride to the organometallic compound at a pressure of from 10 millitorr (1.33 Pa) to 100 torr (13,332 Pa).

9. The method of claim 3, wherein exposing the thin layer of aluminium fluoride to the pulse comprising the organometallic compound comprises:
injecting the organometallic compound into the ALD chamber for a pulse length; and
closing a throttle valve of the ALD system, wherein closing the throttle valve prevents flow of materials into or out of the ALD chamber and maintains the thin layer of aluminium fluoride in contact with the organometallic compound for a shut in period of from 1 second to 60 seconds.

10. The method of claim 9, further comprising:
reopening the throttle valve; and
purging the ALD chamber with an inert gas to remove at least 99% of the residual organometallic compounds, the volatile organometallic compounds, or both from the ALD chamber.

11. The method of claim 1, wherein:
the ALD protective layer comprises a metal fluoride protective coating comprising one or more of aluminium trifluoride (AlF₃), magnesium fluoride (MgF₂), calcium fluoride (CaF₂), lithium fluoride (LiF), lanthanum fluoride (LaF₃), gadolinium fluoride (GdF₃), or combinations of these; and
applying the protective ALD coating on the outer surface of the etched aluminium layer comprises exposing the etched aluminium layer to alternating pulses of a metal precursor and a fluorine source.

12. The method of claim 11, wherein the fluorine source comprises SF₆, an SF₆ plasma, or a plasma comprising SF₆ and argon (Ar).

13. The method of claim 11, wherein the metal precursor comprises an aluminium precursor selected from one or more of trimethylaluminium (TMA), triethylaluminium (TEA), dimethylaluminium isopropoxide (DMAI), [MeC(NiPr)₂]AlEt₂, dimethylaluminiumhydride, dimethylethylamine, ethylpiperidine, dimethylaluminium hydride, or combinations of these.

14. The method of claim 11, wherein the ALD protective layer comprises magnesium fluoride (MgF₂).

15. The method of claim 1, comprising:
depositing a first ALD protective layer on the etched surface of the reflective coating; and
depositing a second ALD protective layer on an outer surface of the first ALD protective layer.

16. The method of claim 1, where the ALD protective layer comprises a high reflective index metal fluoride, wherein the high reflective index metal fluoride increases the reflectance of the enhanced aluminium mirror relative to a mirror comprising only the reflective coating.

17. An enhanced aluminium mirror for ultraviolet optical systems, the enhanced aluminium mirror comprising:
a substrate having a surface;
a reflective coating deposited onto the surface of the substrate, wherein the reflective coating comprises aluminium metal deposited by physical vapor deposition; and
an ALD protective layer deposited onto an etched surface of the reflective coating, wherein:
the ALD protective layer is applied through atomic layer deposition;
the reflective coating reflects light having wavelengths in at least the vacuum ultraviolet wavelength range; and
the ALD protective layer reduces or prevents oxidation of the aluminium of the reflective coating.

18. The enhanced aluminium mirror of claim 17, wherein the reflective coating and the ALD protective layer contain less than 5 atomic percent oxygen atoms.

19. The enhanced aluminium mirror of claim 17, wherein the ALD protective layer comprises a high reflective index metal fluoride, wherein the high reflective index metal fluoride increases the reflectance of the enhanced aluminium mirror relative to a mirror comprising only the reflective coating.

20. The enhanced aluminium mirror of claim 17, wherein the ALD protective layer comprises a first ALD protective layer comprising a first ALD metal fluoride and a second ALD protective layer comprising a second ALD metal fluoride that is different from the first ALD metal fluoride.
